(19) United States
(12) Patent Application Publication
(10) Pub. No.: US 2019/0312054 A1
(43) Pub. Date: Oct. 10, 2019

(54) THREE-DIMENSIONAL SEMICONDUCTOR DEVICE

(71) Applicant: SAMSUNG ELECTRONICS CO., LTD., Suwon-si (KR)

(72) Inventors: Jang Gn YUN, Hwaseong-si (KR); Joon Sung Lim, Seongnam-si (KR); Eun Suk Cho, Suwon-si (KR)

(73) Assignee: SAMSUNG ELECTRONICS CO., LTD., Suwon-si (KR)

(21) Appl. No.: 16/239,130

(22) Filed: Jan. 3, 2019

(30) Foreign Application Priority Data
Apr. 10, 2018 (KR) 10-2018-0041451

(51) Int. Cl. H01L 27/11582; H01L 27/11565

(52) U.S. Cl. CPC H01L 27/11582; H01L 27/11573; H01L 27/11565

(57) ABSTRACT

A three-dimensional semiconductor device and method of fabrication is provided. The three-dimensional semiconductor device includes a stacked structure on a lower structure. The stacked structure includes interlayer insulating layers and gate electrodes. The device also includes a channel structure on the lower structure, with the channel structure including a horizontal portion between the stacked structure and the lower structure. The channel structure also includes a plurality of vertical portions extended in a vertical direction. The device also includes support patterns on the lower structure. In addition, the device includes a gate dielectric structure having a lower portion and upper portions. The method of fabrication includes forming the stacked structure with holes. The method also includes removing a sacrificial layer from a horizontal area above the lower structure and forming a channel structure within the holes and within a horizontal space made by removal of the sacrificial layer.

### CROSS-REFERENCE TO RELATED APPLICATION(S)

This application claims priority from Korean Patent Application No. 10-2018-0041451 filed on Apr. 10, 2018, in the Korean Intellectual Property Office, the disclosure of which is incorporated herein by reference in its entirety.

### BACKGROUND

### 1. Field

The disclosure of this application relates to a semiconductor device, and particularly, to a three-dimensional semiconductor device including stacked gate electrodes.

### 2. Description of Related Art

A semiconductor device including gate electrodes stacked in a direction perpendicular to a surface of a semiconductor substrate has been developed. In order to obtain high integration of such a semiconductor device, the number of the stacked gate electrodes has been increased. There is a limit to increasing the number of gate electrodes stacked in a direction perpendicular to a surface of a semiconductor substrate as described above.

### SUMMARY

An aspect of the disclosure of this application is to provide a three-dimensional semiconductor device capable of improving a degree of integration.

According to an aspect of the disclosure of this application, a three-dimensional semiconductor device is provided. The three-dimensional semiconductor device includes a stacked structure disposed on a lower structure, and including interlayer insulating layers and gate electrodes, alternately stacked, a channel structure disposed on the lower structure and spaced apart from the lower structure, the channel structure including a horizontal portion, between the stacked structure and the lower structure, and a plurality of vertical portions extended from a portion of the horizontal portion in a vertical direction, perpendicular to an upper surface of the lower structure, and passing through the gate electrodes, support patterns disposed on the lower structure and disposed below the stacked structure, and a gate dielectric structure having a lower portion and upper portions, wherein the lower portion of the gate dielectric structure is disposed between a lower surface of the horizontal portion of the channel structure and the lower structure, and between an upper surface of the horizontal portion of the channel structure and the stacked structure, and the upper portions of the gate dielectric structure are disposed between the vertical portions of the channel structure and the stacked structure.

According to an aspect of the disclosure of this application, a three-dimensional semiconductor device is provided. The three-dimensional semiconductor device includes a stacked structure disposed on a semiconductor substrate, and including interlayer insulating layers and gate electrodes, alternately stacked, a channel structure disposed on the semiconductor substrate, the channel structure including a horizontal portion between the stacked structure and the semiconductor substrate and a plurality of vertical portions extended in a vertical direction, perpendicular to an upper surface of the semiconductor substrate, from the horizontal portion and passing through the gate electrodes, a line structure passing through the stacked structure in the vertical direction and extended in a horizontal direction, parallel to the upper surface of the semiconductor substrate, and an impurity region disposed in the horizontal portion of the channel structure adjacent to the line structure.

According to an aspect of the disclosure of this application, a three-dimensional semiconductor device is provided. The three-dimensional semiconductor device includes a stacked structure disposed on a semiconductor substrate, the stacked structure including gate electrodes stacked in a vertical direction, perpendicular to an upper surface of the semiconductor substrate, a channel structure disposed on the semiconductor substrate, and spaced apart from the semiconductor substrate, the channel structure including a horizontal portion between the stacked structure and the semiconductor substrate and a plurality of vertical portions extended continuously in the vertical direction from the horizontal portion and passing through the gate electrodes, a line structure passing through the stacked structure in the vertical direction and electrically connected to the horizontal portion of the channel structure, support patterns disposed on the semiconductor substrate and disposed below the stacked structure, and a gate dielectric structure having a lower portion and upper portions, wherein the lower portion of the gate dielectric structure is disposed between a lower surface of the horizontal portion of the channel structure and the semiconductor substrate, and between an upper surface of the horizontal portion of the channel structure and the stacked structure, and the upper portions of the gate dielectric structure are disposed between the vertical portions of the channel structure and the stacked structure.

In addition, this application discloses a method for forming a VNAND (Vertical NAND) flash memory device, the method including: forming a support structure and a sacrificial layer on a substrate; forming a molded structure on the support structure and the sacrificial layer; forming holes passing through the molded structure, wherein the holes are configured to expose a portion of the sacrificial layer; forming a horizontal space by removing the sacrificial layer; and forming a channel structure in the horizontal space and in the holes.

In some embodiments, the method includes forming a channel structure including: after removing the sacrificial layer: forming a gate dielectric structure in the horizontal space and in the holes. And the method sometimes includes after forming the gate dielectric structure: forming a silicon layer on the gate dielectric structure.

In some embodiments, a first portion of the silicon layer includes a first impurity region having an n-type conductivity, wherein the first impurity region is configured to be a common source line.

In addition, in some embodiments of the method, a second portion of the silicon layer includes a second impurity region having a p-type conductivity configured to apply a body voltage to the channel structure.

In some embodiments of the method, the silicon layer includes polysilicon.

### BRIEF DESCRIPTION OF DRAWINGS

The above and other aspects, features and other advantages of the present disclosure will be more clearly understood from the following detailed description, taken in conjunction with the accompanying drawings, in which:

FIG. 1A is a schematic block diagram of a three-dimensional semiconductor device according to an example embodiment;

FIG. 1B is a schematic block diagram of an exemplary example of a three-dimensional semiconductor device according to an example embodiment;

FIG. 2 is a plan view illustrating an exemplary example of a three-dimensional semiconductor device according to an example embodiment;

FIGS. 3A and 3B are cross-sectional views illustrating an exemplary example of a three-dimensional semiconductor device according to an example embodiment;

FIGS. 4A, 4B, 5, and 6 are partially enlarged views illustrating an exemplary example of a three-dimensional semiconductor device according to an example embodiment;

FIGS. 7A and 7B are partially enlarged views illustrating a modified example of a three-dimensional semiconductor device according to an example embodiment;

FIG. 8 is a partially enlarged view illustrating a modified example of a three-dimensional semiconductor device according to an example embodiment;

FIGS. 9A and 9B are partially enlarged views illustrating a modified example of a three-dimensional semiconductor device according to an example embodiment;

FIGS. 10A and 10B are partially enlarged views illustrating an exemplary example of a three-dimensional semiconductor device according to an example embodiment;

FIGS. 11 and 12 are partially enlarged views illustrating a modified example of a three-dimensional semiconductor device according to an example embodiment;

FIG. 13A is a schematic perspective view illustrating an exemplary example of a three-dimensional semiconductor device according to an example embodiment;

FIG. 13B is a schematic perspective view illustrating a modified example of a three-dimensional semiconductor device according to an example embodiment;

FIGS. 14A and 14B are cross-sectional views illustrating a modified example of a three-dimensional semiconductor device according to an example embodiment;

FIG. 15A is a partially enlarged view illustrating a modified example of a three-dimensional semiconductor device according to an example embodiment;

FIG. 15B is a partially enlarged view illustrating a modified example of a three-dimensional semiconductor device according to an example embodiment;

FIG. 16 is a plan view illustrating a modified example of a three-dimensional semiconductor device according to an example embodiment;

FIGS. 17A and 17B are cross-sectional views illustrating a modified example of a three-dimensional semiconductor device according to an example embodiment;

FIG. 18 is a cross-sectional view illustrating a modified example of a three-dimensional semiconductor device according to an example embodiment;

FIG. 19 is a plan view illustrating a modified example of a three-dimensional semiconductor device according to an example embodiment;

FIG. 20 is a cross-sectional view illustrating a modified example of a three-dimensional semiconductor device according to an example embodiment;

FIG. 21 is a partially enlarged view illustrating a modified example of a three-dimensional semiconductor device according to an example embodiment;

FIG. 22 is a partially enlarged view illustrating a modified example of a three-dimensional semiconductor device according to an example embodiment;

FIG. 23 is a plan view illustrating a modified example of a three-dimensional semiconductor device according to an example embodiment;

FIG. 24 is a cross-sectional view illustrating a modified example of a three-dimensional semiconductor device according to an example embodiment;

FIG. 25 is a partially enlarged view illustrating a modified example of a three-dimensional semiconductor device according to an example embodiment;

FIG. 26 is a partially enlarged view illustrating a modified example of a three-dimensional semiconductor device according to an example embodiment;

FIG. 27 is a plan view illustrating a modified example of a three-dimensional semiconductor device according to an example embodiment;

FIG. 28 is a cross-sectional view illustrating a modified example of a three-dimensional semiconductor device according to an example embodiment;

FIG. 29 is a cross-sectional view illustrating a modified example of a three-dimensional semiconductor device according to an example embodiment;

FIG. 30 is a plan view illustrating a modified example of a three-dimensional semiconductor device according to an example embodiment;

FIG. 31 is a cross-sectional view illustrating a modified example of a three-dimensional semiconductor device according to an example embodiment;

FIGS. 32A and 32B are cross-sectional views illustrating a modified example of a three-dimensional semiconductor device according to an example embodiment;

FIG. 33 is a partially enlarged view illustrating a modified example of a three-dimensional semiconductor device according to an example embodiment;

FIG. 34 is a plan view illustrating a modified example of a three-dimensional semiconductor device according to an example embodiment;

FIG. 35 is a cross-sectional view illustrating a modified example of a three-dimensional semiconductor device according to an example embodiment;

FIGS. 36A and 36B are cross-sectional views illustrating a modified example of a three-dimensional semiconductor device according to an example embodiment;

FIG. 37 is a plan view illustrating a modified example of a three-dimensional semiconductor device according to an example embodiment;

FIG. 38 is a perspective view illustrating a modified example of a three-dimensional semiconductor device according to an example embodiment;

FIG. 39 is a plan view illustrating a modified example of a three-dimensional semiconductor device according to an example embodiment;

FIG. 40A is a plan view illustrating a modified example of a three-dimensional semiconductor device according to an example embodiment;

FIG. 40B is a plan view illustrating a modified example of a three-dimensional semiconductor device according to an example embodiment;

FIG. 41 is a cross-sectional view illustrating a modified example of a three-dimensional semiconductor device according to an example embodiment;

FIG. 42 is a plan view illustrating a modified example of a three-dimensional semiconductor device according to an example embodiment;

FIG. 43 is a plan view illustrating a modified example of a three-dimensional semiconductor device according to an example embodiment;

FIG. 44A is a cross-sectional view illustrating a modified example of a three-dimensional semiconductor device according to an example embodiment;

FIG. 44B is a partially enlarged view illustrating a modified example of a three-dimensional semiconductor device according to an example embodiment;

FIG. 45 is a cross-sectional view illustrating a modified example of a three-dimensional semiconductor device according to an example embodiment;

FIG. 46 is a plan view illustrating a modified example of a three-dimensional semiconductor device according to an example embodiment;

FIGS. 47A and 47B are cross-sectional views illustrating a modified example of a three-dimensional semiconductor device according to an example embodiment;

FIG. 48 is a plan view illustrating a modified example of a three-dimensional semiconductor device according to an example embodiment;

FIG. 49 is a process flow chart illustrating an exemplary example of a method for forming a three-dimensional semiconductor device according to an example embodiment; and

FIGS. 50 to 57 are cross-sectional views illustrating an exemplary example of a method for forming a three-dimensional semiconductor device according to an example embodiment.

### DETAILED DESCRIPTION

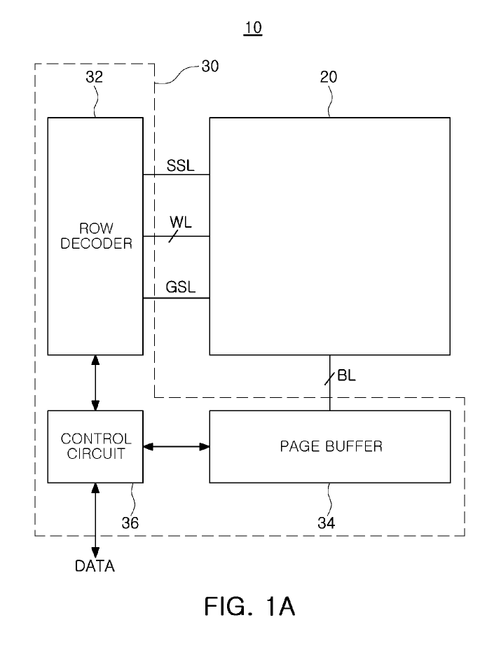

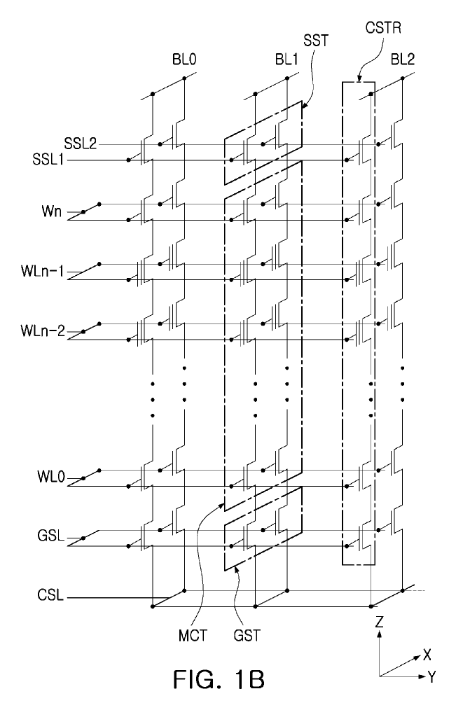

Referring to FIG. 1A, an exemplary example of a three-dimensional semiconductor device according to an example embodiment will be described. FIG. 1A is a schematic block diagram of a three-dimensional semiconductor device according to an example embodiment.

Referring to FIG. 1A, a three-dimensional semiconductor device 10 according to an example embodiment may include a memory cell array region 20 and a peripheral circuit region 30. The memory cell array region 20 may include a plurality of memory cells. The peripheral circuit region 30 may include a row decoder 32, a page buffer 34, and a control circuit 36.

The plurality of memory cells, in the memory cell array region 20, may be connected to the row decoder 32 through a string select line SSL, a word line WL, and a ground select line GSL, and may be connected to the page buffer 34 through a bit line BL.

In example embodiments, a plurality of memory cells, arranged along the same row, are commonly connected to a word line WL, while a plurality of memory cells, arranged along the same column, may be commonly connected to a bit line BL.

The row decoder 32 may decode an address, having been input, to generate and transmit driving signals of the word line WL. The row decoder 32 may provide a word line voltage, generated from a voltage generating circuit in the control circuit 36, in response to the control of the control circuit 36, to a selected word line, among the word lines WL, and a non-selected word line, among the word lines WL.

The page buffer 34 may be connected to the memory cell array region 20 through the bit line BL, to read data, stored in the memory cell. The page buffer 34 may temporarily store data, which is to be stored in the memory cell, or may sense data, stored in the memory cell, depending on a mode of operation. The page buffer 34 may include a column decoder and a sense amplifier.

The column decoder may selectively activate a bit line BL of the memory cell array region 20, while the sense amplifier may sense a voltage of a bit line BL, selected by the column decoder, to read data, stored in a selected memory cell, during a reading operation. The control circuit 36 may control operations of the row decoder 32 and the page buffer 34. The control circuit 36 may receive a control signal, transmitted from an external source, and an external voltage, and may be operated according to a received control signal. The control circuit 36 may include a voltage generating circuit, generating voltages required for an internal operation using an external voltage, for example, a programming voltage, a reading voltage, an erasing voltage, and the like. The control circuit 36 may control reading, writing, and/or erasing operations in response to the control signals. Moreover, the control circuit 36 may include an input and output circuit. The input and output circuit may receive data DATA and transmit data to the page buffer 34 in a programming operation, and may output the data DATA, transmitted from the page buffer 34, to an outside in a reading operation.

Referring to FIG. 1B, an exemplary example of a circuit of the memory cell array region (20 of FIG. 1A) of the three-dimensional semiconductor device 10, illustrated in FIG. 1A will be described. FIG. 1B is a circuit diagram schematically illustrating the memory cell array region (20 of FIG. 1A).

Referring to FIG. 1B, a three-dimensional semiconductor device according to an example embodiment may include a common source line CSL, bit lines BL0 to BL2, and a plurality of cell strings CSTR, disposed between the common source line CSL and the bit lines BL0 to BL2. The plurality of cell strings CSTR may be connected to each of the bit lines BL0 to BL2 in parallel. The plurality of cell strings CSTR may be commonly connected to the common source line CSL. Each of the plurality of cell strings CSTR may include a lower select transistor GST, memory cells MCT, and an upper select transistor SST, which may be connected in series.

The memory cells MCT may be connected between the lower select transistor GST and the upper select transistor SST in series. Each of the memory cells MCT may include data storage elements, which may store data.

The upper select transistor SST may be electrically connected to the bit lines BL0 to BL2, while the lower select transistor GST may be electrically connected to the common source line CSL.

The upper select transistor SST may be provided as a plurality of upper select transistors, and may be controlled by the string select lines SSL1 to SSL2. The memory cells MCT may be controlled by the plurality of word lines WL0 to WLn.

The lower select transistor GST may be controlled by the ground select line GSL. The common source line CSL may be commonly connected to a source of the ground select transistor GST.

In one example, the upper select transistor SST may be a string select transistor, while upper select lines SSL1 to SSL2 may be a string select line. The lower select transistor GST may be a ground select transistor.

Hereinafter, referring to the drawings, a structure of the three-dimensional semiconductor device 10 according to an example embodiment will be described. In the drawings, a plan view and a cross-sectional view may illustrate a portion of components for explaining a semiconductor device according to an example embodiment. For example, a plan view may illustrate a portion of components among components illustrated in a cross-sectional view.

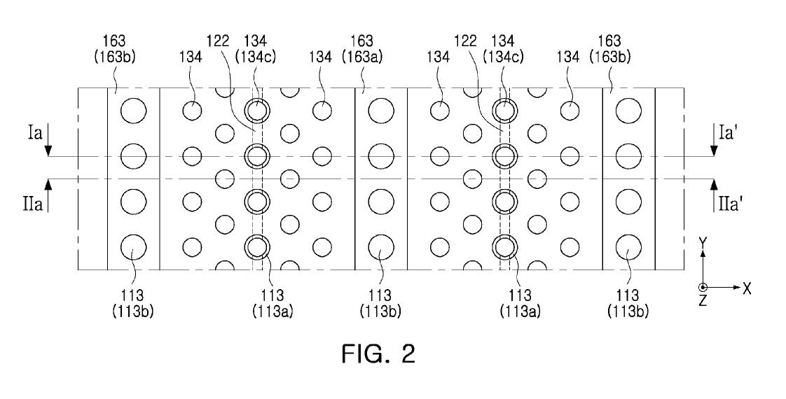

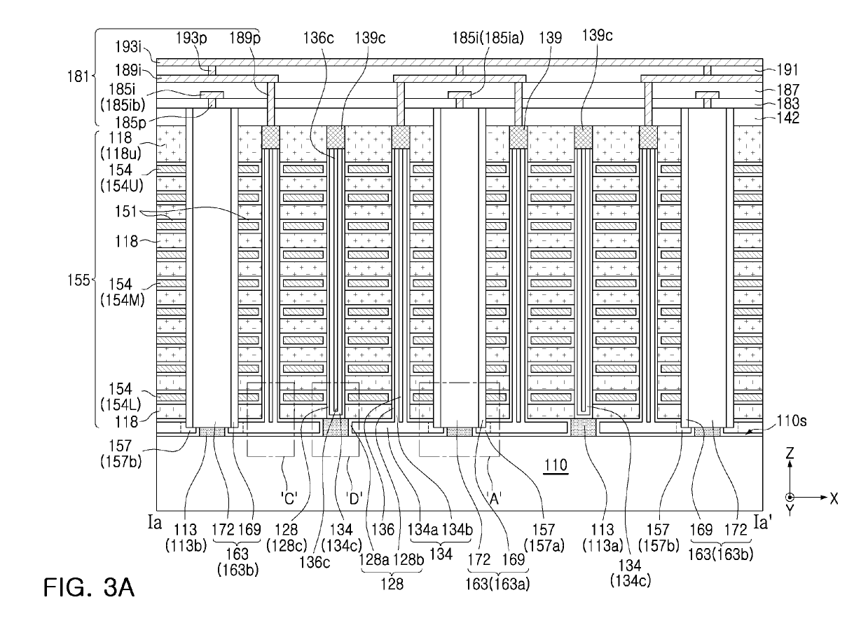

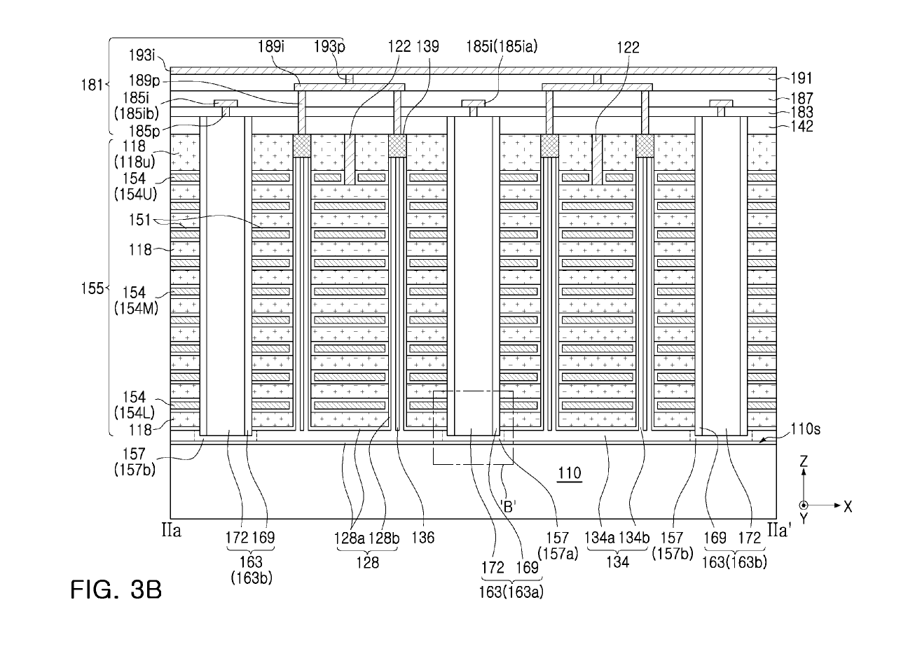

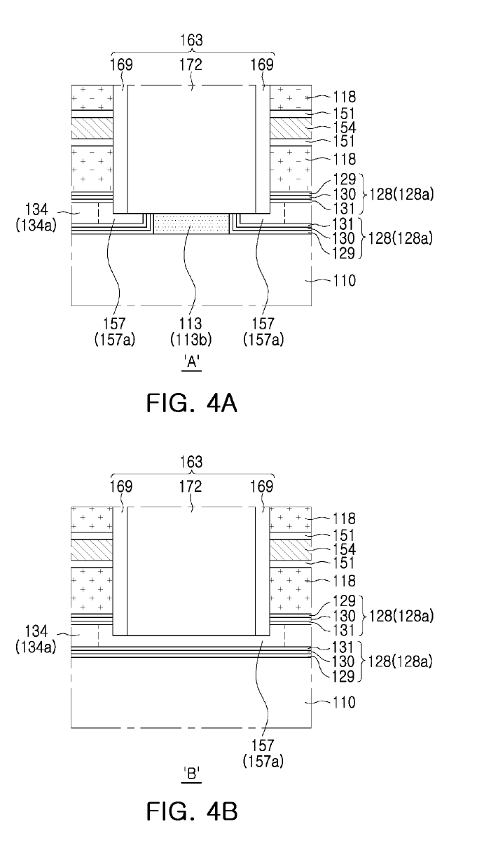

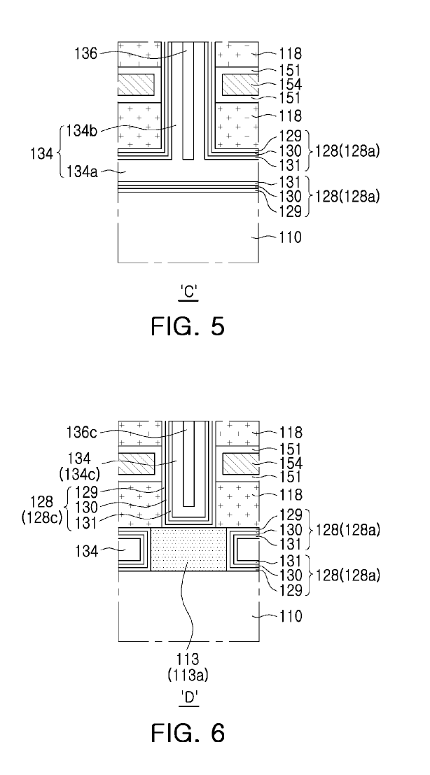

FIG. 2 is a plan view illustrating a three-dimensional semiconductor device according to an example embodiment, FIG. 3A is a cross-sectional view illustrating a region taken along line Ia-Ia′ of FIG. 2, and FIG. 3B is a cross-sectional view illustrating a region taken along line IIa-IIa′ of FIG. 2. FIG. 4A is a partially enlarged view enlarging a portion indicated by ‘A’ of FIG. 3A, FIG. 4B is a partially enlarged view enlarging a portion indicated by ‘B’ of FIG. 3B, FIG. 5 is a partially enlarged view enlarging a portion indicated by ‘C’ of FIG. 3A, and FIG. 6 is a partially enlarged view enlarging a portion indicated by ‘D’ of FIG. 3A.

Referring to FIGS. 2, 3A, 3B, 4A, 4B, 5, and 6, a lower structure 110 may be provided. In one example, the lower structure 110 may include a semiconductor substrate. For example, the lower structure 110 may be a semiconductor substrate, including a semiconductor material, such as silicon (e.g., polysilicon or single crystal silicon), or the like.

A stacked structure 155 may be disposed on the lower structure 110. The stacked structure 155 may be spaced apart from the lower structure 110. A first capping insulating layer 142 may be disposed on the stacked structure 155.

The stacked structure 155 may include interlayer insulating layers 118 and gate electrodes 154, alternately stacked. The interlayer insulating layers 118 may be spaced apart from each other and stacked in a direction perpendicular to an upper surface 110s of the semiconductor substrate of the lower structure 110. The gate electrodes 154 may be disposed between the interlayer insulating layers 118. The interlayer insulating layers 118 may include silicon oxide, while the gate electrodes 154 may include a conductive material (e.g., doped silicon, Ti, W, TiN, and/or TaN). A top interlayer insulating layer 118u, of the interlayer insulating layers 118, may be thicker than respective interlayer insulating layers, located below the top interlayer insulating layer 118u.

The gate electrodes 154 may include a lower gate electrode 154L, an upper gate electrode 154U, and intermediate gate electrodes 154M, between the lower gate electrode 154L and the upper gate electrode 154U. The lower gate electrode 154L may be a ground select line (GSL of FIGS. 1A and 1B), while the upper gate electrode 154U may be a string select line (SSL of FIGS. 1A and 1B). At least a portion of the intermediate gate electrodes 154M may be a word line (WL of FIG. 1A and WL0 to WLn of FIG. 1B).

Insulating separation patterns 122, passing through the top interlayer insulating layer 118u, of the interlayer insulating layers 118, and at least a top gate electrode, of the gate electrodes 154, that is, the upper gate electrode 154U, may be provided. The insulating separation patterns 122 may include silicon oxide.

Line structures 163, passing through the first capping insulating layer 142 and the stacked structure 155, may be provided. The line structures 163 may pass through the stacked structure 155 in a vertical direction Z, perpendicular to the upper surface 110s of the lower structure 110, and may be extended in a first horizontal direction Y, parallel to the upper surface 110s of the lower structure 110. The line structures 163 may include a first line structure 163a and a second line structure 163b.

The line structures 163 may include conductive patterns 172 and insulating spacers 169. The insulating spacers 169 may be disposed on side surfaces of the conductive patterns 172, and may allow the conductive patterns 172 and the gate electrodes 154 to be spaced apart from each other.

Support patterns 113 may be disposed on the lower structure 110. The support patterns 113 may be disposed below the stacked structure 155. Each of the support patterns 113 may have a circular shape in a plan view.

When viewed in a first horizontal direction Y, parallel to the upper surface 110s of the lower structure 110, and a second horizontal direction X, perpendicular thereto, each of the support patterns 113 may have a width smaller than that of each of the line structures 163. The support patterns 113 may include an insulating material or a semiconductor material.

The support patterns 113 may include first support patterns 113a and second support patterns 113b, spaced apart from each other. The first support patterns 113a and the second support patterns 113b may have lower surfaces coplanar with each other. The second support patterns 113b may be disposed between the line structures 163 and the lower structure 110. The first support patterns 113a may be disposed between the lower structure 110 and the stacked structure 155.

A channel structure 134 may be disposed on the lower structure 110. The channel structure 134 may be spaced apart from the lower structure 110. The channel structure 134 may include a horizontal portion 134a, interposed between the stacked structure 155 and the lower structure 110, as well as vertical portions 134b, extended in the vertical direction Z, perpendicular to the upper surface 110s of the semiconductor substrate of the lower structure 110 from the horizontal portion 134a. The vertical portions 134b of the channel structure 134 may pass through the gate electrodes 154 of the stacked structure 155. In the channel structure 134, the vertical portions 134b may be extended continuously, without an interface in the vertical direction Z from a portion of the horizontal portion 134a. Thus, the channel structure 134 may be formed to have an integral structure.

The horizontal portion 134a of the channel structure 134 may be electrically connected to the conductive patterns 172 of the line structures 163. The horizontal portion 134a of the channel structure 134 may be in contact with the conductive patterns 172 of the line structures 163. The horizontal portion 134a of the channel structure 134 may oppose the support patterns 113.

Core layers 136, disposed on the lower structure 110 and surrounded by the vertical portions 134b of the channel structure 134, may be provided. The core layers 136 may include an insulating material.

Pad layers 139 may be disposed on the core layers 136. The pad layers 139 may be in contact with the vertical portions 134b of the channel structure 134. In one example, the pad layers 139 may include silicon having an n-type conductivity.

A first gate dielectric structure 128, including a lower portion 128a and an upper portion 128b, may be provided. The lower portion 128a of the first gate dielectric structure 128 may be disposed between the horizontal portion 134a of the channel structure 134 and the lower structure 110, and between the horizontal portion 134a of the channel structure 134 and the stacked structure 155. A portion of the lower portion 128a of the first gate dielectric structure 128 may be extended in the vertical direction Z to be disposed on side surfaces of the support patterns 113. The upper portion 128b of the first gate dielectric structure 128 may be extended in the vertical direction Z from the lower portion 128a, disposed between the horizontal portion 134a and the stacked structure 155. The upper portion 128b may be disposed between the vertical portions 134b of the channel structure 134 and the stacked structure 155.

The first gate dielectric structure 128 may include a layer in which data may be stored. For example, the first gate dielectric structure 128 may include a tunnel dielectric 131, a data storage layer 130, and a blocking dielectric 129. The data storage layer 130 may be disposed between the tunnel dielectric 131 and the blocking dielectric 129. The blocking dielectric 129 may be adjacent to the stacked structure 155, while the tunnel dielectric 131 may be adjacent to the channel structure 134.

The tunnel dielectric 131 may include silicon oxide and/or impurity-doped silicon oxide. The blocking dielectric 129 may include silicon oxide and/or high dielectric. The data storage layer 130 may be a layer for storing data, between the channel structure 134 and the intermediate gate electrodes 154M, which may be word lines. For example, the data storage layer 130 may include a material, for example, silicon nitride. In this case, the material may trap and retain an electron, injected through the tunnel dielectric 131 from the channel structure 134, or erase an electron, trapped in the data storage layer 130, depending on the operating conditions of a nonvolatile memory device, such as a flash memory device.

In one example, the first gate dielectric structure 128 may include an additional gate dielectric 128c, disposed on the first support patterns 113a, while the channel structure 134 may include an additional channel layer 134c, disposed on the first support patterns 113a. The additional gate dielectric 128c may be disposed to surround a bottom surface and a side surface of the additional channel layer 134c. The additional channel layer 134c is disposed between the insulating separation patterns 122, and may be extended in a direction toward the lower structure 110 to pass through the gate electrodes 154. An additional core layer 136c, surrounded by the additional channel layer 134c, and an additional pad layer 139c, in contact with the additional channel layer 134c on the additional core layer 136c, may be provided. The additional gate dielectric 128c and the additional channel layer 134c may pass through the gate electrodes 154 of the stacked structure 155.

In one example, the additional gate dielectric 128c may be spaced apart from the lower portion 128a and the upper portion 128b of the first gate dielectric structure 128. The additional channel layer 134c may be spaced apart from the horizontal portion 134a and the vertical portion 134b of the channel structure 134. Here, the ‘additional channel layer’ and the ‘additional gate dielectric’ may be replaced by the terms ‘dummy channel layer’ and ‘dummy gate dielectric’, respectively.

The stacked structure 155 may include a second gate dielectric 151, interposed between the gate electrodes 154 and the interlayer insulating layers 118 and extended between the gate electrodes 154 and the first gate dielectric structure 128. The second gate dielectric 151 may include a high dielectric (e.g., AlO, or the like).

In one example, impurity regions 157 may be disposed in the horizontal portion 134a of the channel structure 134 adjacent to the line structures 163. The impurity regions 157 may be in contact with the line structure 163.

In one example, the impurity regions 157 may be an n-type conductivity. However, a technical idea of the application is not limited thereto. For example, the impurity regions 157 may include a first impurity region 157a adjacent to the first line structure 163a and having a first conductivity as well as a second impurity region 157b adjacent to the second line structure 163b and having a second conductivity, different from the first conductivity. Here, one of the first conductivity and the second conductivity may be an n-type, while the other may be a p-type. For example, the first impurity region 157a may be an n-type conductivity, while the second impurity region 157b may be a p-type conductivity. The first impurity region 157a, having an n-type conductivity, may serve as the common source line (CSL of FIG. 1B) described with reference to FIG. 1B, and the pad layers 139, on the channel structure 134, may serve as a drain while having an n-type conductivity. The second impurity region 157b, having a p-type conductivity, may be a body impurity region, capable of applying a body voltage to the channel structure 134.

The conductive pattern 172 of the first line structure 163a may be electrically connected while being in contact with the first impurity region 157a, and the conductive pattern 172 of the second line structure 163b may be electrically connected while being in contact with the second impurity region 157b.

A second capping insulating layer 183, a third capping insulating layer 187, and a fourth capping insulating layer 191 may be disposed on the first capping insulating layer 142 in sequence.

First wirings 185i may be disposed on the second capping insulating layer 183. The first wirings 185i may be electrically connected to the conductive patterns 172 of the line structures 163 through contact plugs 185p passing through the second capping insulating layer 183.

Among the first wirings 185i, a portion 185ia of wirings may be electrically connected to the conductive pattern 172 of the first line structure 163a, and the other portion 185ib of wirings may be electrically connected to the conductive pattern 172 of the second line structure 163b.

Second wirings 193i may be disposed on the fourth capping insulating layer 191. The second wiring 193i may be a bit line. Bit line lower plugs 189p, passing through the first capping insulating layer 142, the second capping insulating layer 183, and the third capping insulating layer 187, and electrically connected to the pad layers 139, an intermediate connection pattern 189i, disposed on the third capping insulating layer 187 and electrically connected to a plurality of bit line lower plugs 189p, as well as a bit line upper plug 193p, allowing the intermediate connection pattern 189i and the bit line 193i to be electrically connected to each other, may be provided. Thus, the second wiring, that is, the bit line 193i may be electrically connected to the pad layers 139 through the bit line lower plugs 189p, the intermediate connection pattern 189i, and the bit line upper plug 193p.

The first wirings 185i, the contact plugs 185p, the bit line lower plugs 189p, the intermediate connection pattern 189i, the bit line upper plug 193p, and the bit line 193i may form a interconnection structure 181. In one example, the layout and arrangement position of components forming the interconnection structure 181 may be not limited to those illustrated in FIGS. 3A and 3B, and may be variously modified.

Hereinafter, a detailed description of the cited elements will be omitted and a modified part of the cited components will be mainly described, while referring directly to the components described above. Therefore, the components described above can be directly cited without any particular explanation, and can be modified within the scope of the technical idea of the present disclosure.

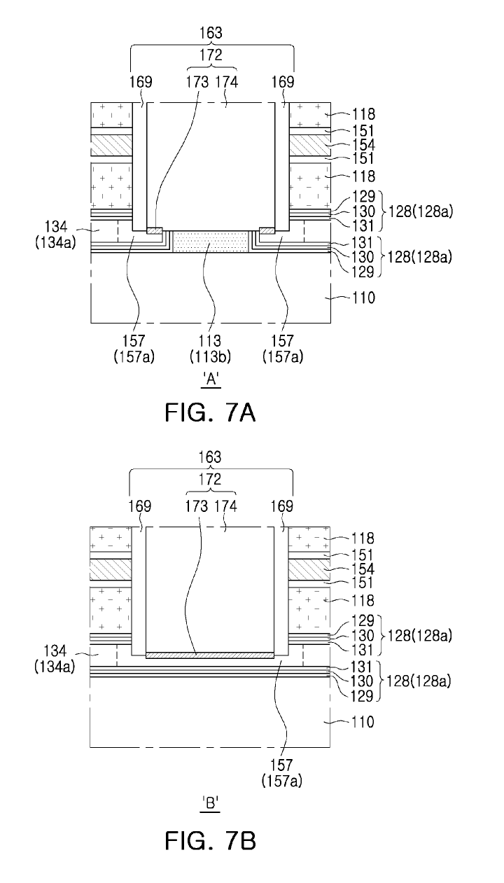

Next, referring to FIGS. 7A and 7B, an exemplary example of the line structures 163 and an exemplary example of the support patterns 113 will be described. FIG. 7A is a partially enlarged view enlarging a portion indicated by ‘A’ of FIG. 3A, while FIG. 7B is a partially enlarged view enlarging a portion indicated by ‘B’ of FIG. 3B.

Referring to FIGS. 7A and 7B, in an exemplary example, the support patterns 113 may include an insulating material, such as, silicon oxide, or the like. The conductive pattern 172 of the line structures 163 may include a metal-silicide layer 173, in contact with and electrically connected to the horizontal portion 134a of the channel structure 134, and a conductive layer 174 on the metal-silicide layer 173. The conductive layer 174 may include a metal material such as tungsten, or the like.

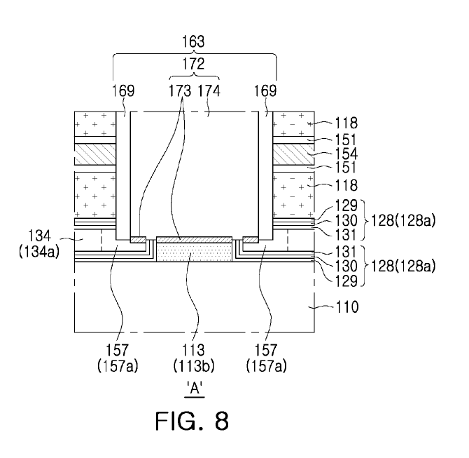

Next, referring to FIG. 8, an exemplary example of the line structures 163 and an exemplary example of the support patterns 113 will be described. FIG. 8 is a partially enlarged view enlarging a portion indicated by ‘A’ of FIG. 3A.

Referring to FIG. 8, in an exemplary example, the support patterns 113 may include a semiconductor material, such as silicon, silicon germanium, or the like. The conductive pattern 172 of the line structures 163 may include a metal-silicide layer 173, in contact with and electrically connected to the horizontal portion 134a of the channel structure 134 and the support patterns 113, as well as a conductive layer 174 on the metal-silicide layer 173.

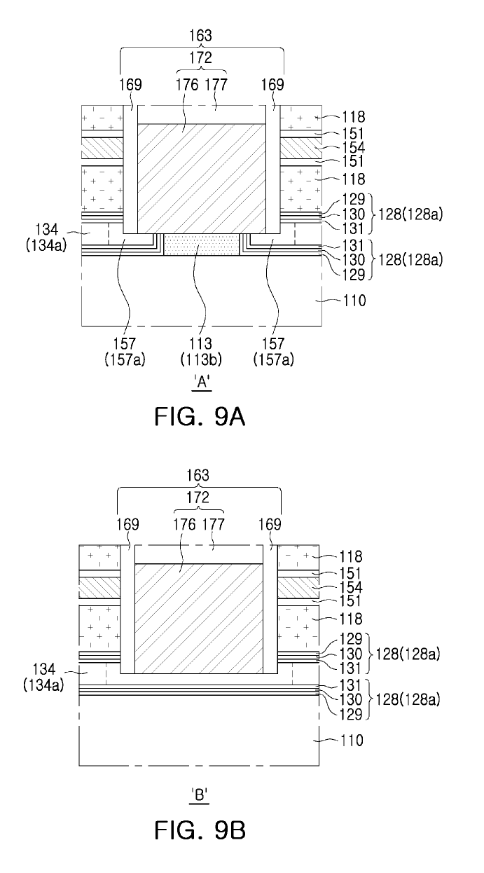

Next, referring to FIGS. 9A and 9B, an exemplary example of the line structures 163 will be described. FIG. 9A is a partially enlarged view enlarging a portion indicated by ‘A’ of FIG. 3A, while FIG. 9B is a partially enlarged view enlarging a portion indicated by ‘B’ of FIG. 3B.

Referring to FIGS. 9A and 9B, in an exemplary example, the conductive pattern 172 of the line structures 163 may include a first material layer 176 and a second material layer 177 on the first material layer 176. The first material layer 176 may be doped silicon having conductivity, while the second material layer 177 may be a metal layer.

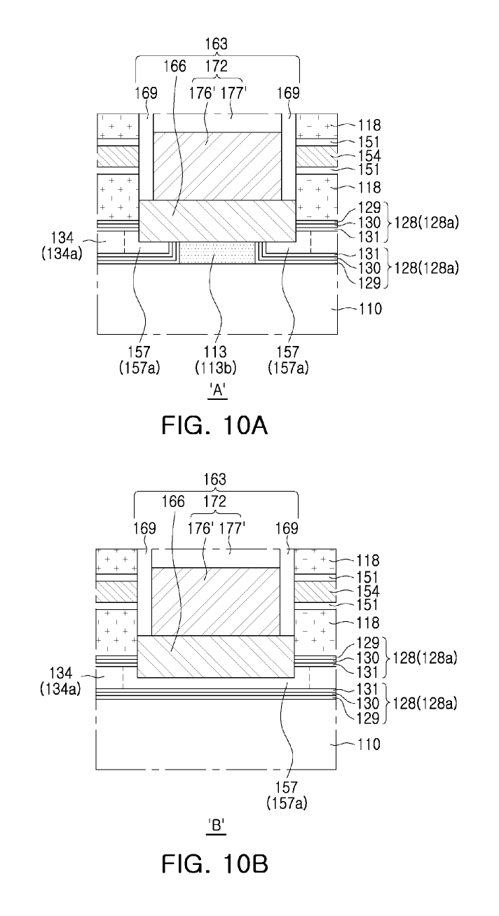

Next, referring to FIGS. 10A and 10B, an exemplary example of the line structures 163 will be described. FIG. 10A is a partially enlarged view enlarging a portion indicated by ‘A’ of FIG. 3A, while FIG. 10B is a partially enlarged view enlarging a portion indicated by ‘B’ of FIG. 3B.

Referring to FIGS. 10A and 10B, in an exemplary example, the line structures 163 may include a lower material layer 166 in contact with the support patterns 113 and the horizontal portion 134a of the channel structure 134, a conductive pattern 172 disposed on the lower material layer 166, and insulating spacers 169 disposed on the lower material layer 166 and disposed on side surfaces of the conductive pattern 172.

The lower material layer 166 may be a material such as silicon, silicon-germanium, or the like. For example, the lower material layer 166 may be silicon formed using a selective epitaxial growth (SEG) process. The conductive pattern 172 may include a first material layer 176′ in contact with the lower material layer 166 and a second material layer 177′ on the first material layer 176′. The first material layer 176′ may include doped silicon, while the second material layer 177′ may include a metal.

Next, referring to FIG. 11, an exemplary example of the channel structure 134 and the first gate dielectric structure 128 will be described. FIG. 11 is a partially enlarged view enlarging a portion indicated by ‘C’ of FIG. 3A.

Referring to FIG. 11, in an exemplary example, the channel structure 134 may include a lower portion 134d extended from the horizontal portion 134a into the lower structure 110. In the channel structure 134, the lower portion 134d may oppose the vertical portion 134b. The lower portion 128a of the first gate dielectric structure 128 may be extended between the lower portion 134d of the channel structure 134 and the lower structure 110, and may allow the channel structure 134 and the lower structure 110 to be spaced apart from each other.

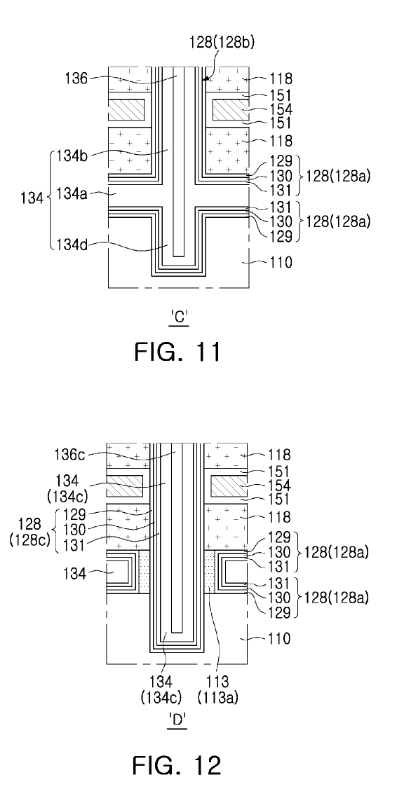

Next, referring to FIG. 12, an exemplary example of the additional channel layer 134c, the additional gate dielectric 128c, and the additional core layer 136c will be described. FIG. 12 is a partially enlarged view enlarging a portion indicated by ‘D’ of FIG. 3A.

Referring to FIG. 12, in an exemplary example, the additional channel layer 134c, the additional gate dielectric 128c, and the additional core layer 136c may pass through the support patterns 113 to be extended into the lower structure 110.

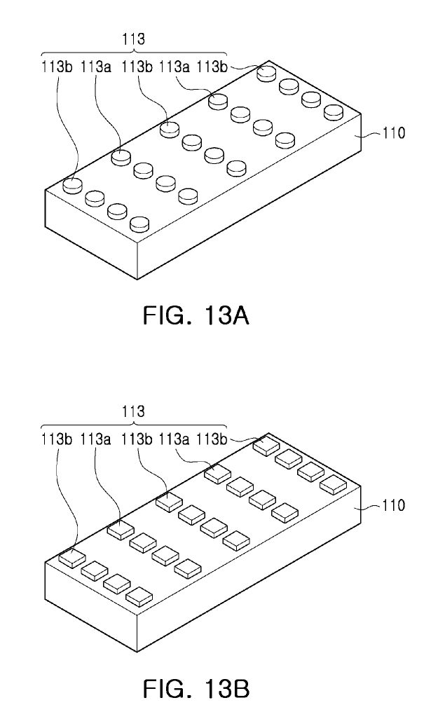

Next, referring to FIGS. 13A and 13B, an exemplary form of the support patterns 113 will be described.

First, referring to FIG. 13A, each of the first support patterns 113a and the second support patterns 113b of the support patterns 113 may have a form of a circular cylinder, protruding from the lower structure 110.

Next, referring to FIG. 13B, each of the first support patterns 113a and the second support patterns 113b of the support patterns 113 may have a form of a rectangular cylinder, protruding from the lower structure 110.

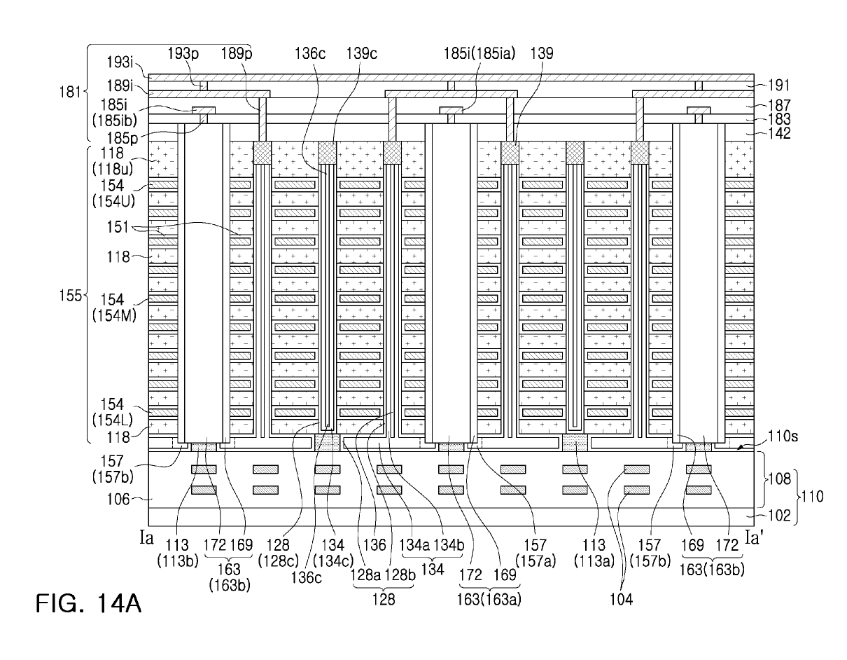

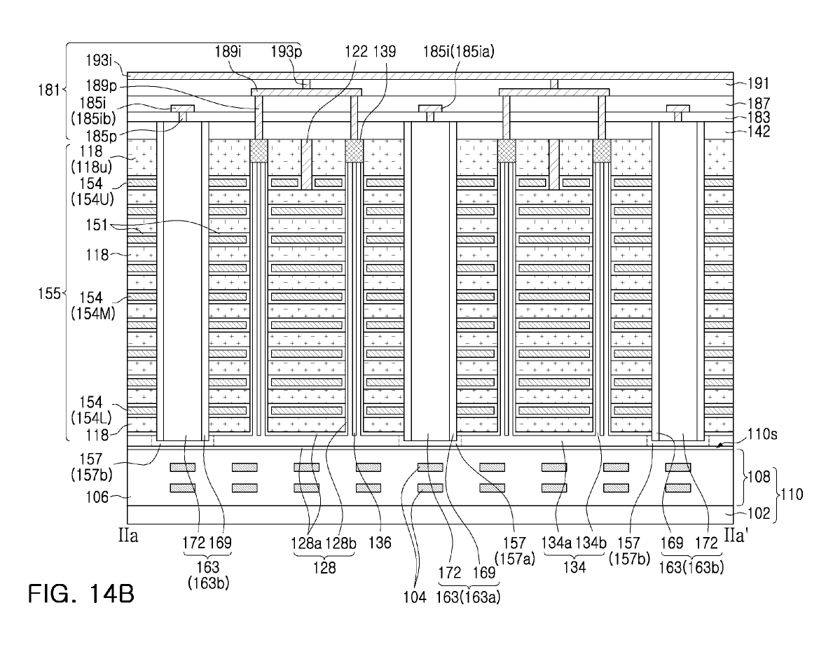

The lower structure 110, described previously, may be provided as a semiconductor substrate, but a technical idea of the application is not limited thereto. For example, the lower structure 110 may be modified to include a portion of the peripheral circuit region (30 of FIG. 1A) described with reference to FIG. 1A. A modified example of the lower structure 110, described above, will be described with reference to FIGS. 14A and 14B. FIG. 14A is a cross-sectional view illustrating a region taken along line Ia-Ia′ of FIG. 2, while FIG. 14B is a cross-sectional view illustrating a region taken along line IIa-IIa′ of FIG. 2.

Referring to FIGS. 2, 14A, and 14B, in an exemplary example, the lower structure 110 may include a semiconductor substrate 102 and a peripheral circuit structure 108 disposed on the semiconductor substrate 102. The peripheral circuit structure 108 may include a peripheral circuit 104 (or a peripheral circuit wiring) and a lower insulating structure 106 covering the peripheral circuit 104. The peripheral circuit 104 may form at least a portion of the peripheral circuit region (30 of FIG. 1A) described with reference to FIG. 1A. The lower insulating structure 106 of the lower structure 110 may include silicon oxide and/or silicon nitride. Thus, the support patterns 113, described above, and a portion of the lower structure 110, adjacent to the first gate dielectric structure 128, for example, an upper portion of the lower insulating structure 106, may include silicon oxide or silicon nitride.

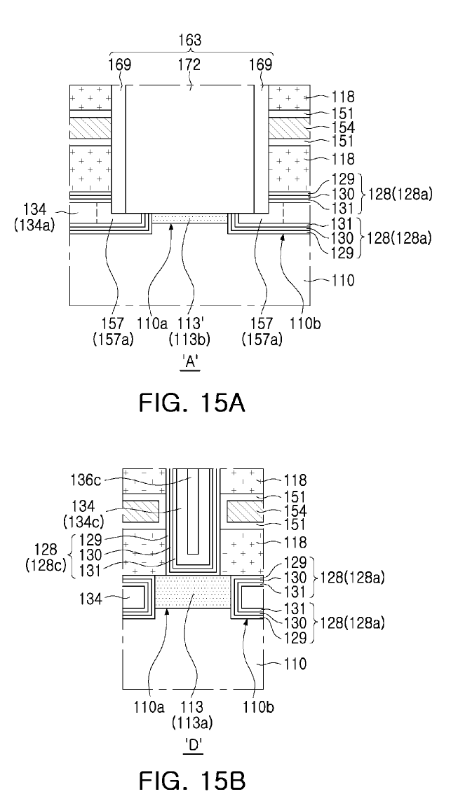

In the example embodiments described previously, an interface between the support patterns 113 and the lower structure 110 may be coplanar with an interface between the first gate dielectric structure 128 and the lower structure 110. However, the technical idea of the present disclosure is not limited thereto, and the relationship of the interface between the support patterns 113 and the lower structure 110 and the interface between the first gate dielectric structure 128 and the lower structure 110 may be modified. The modified example, described above, will be described with reference to FIGS. 15A and 15B. FIG. 15A is a partially enlarged view enlarging a portion indicated by ‘A’ of FIG. 3A, while FIG. 15B is a partially enlarged view enlarging a portion indicated by ‘D’ of FIG. 3A.

Referring to FIGS. 15A and 15B, support patterns 113′ may be formed of a material different from that of a portion of the lower structure 110 adjacent to the support patterns 113′. For example, when the support patterns 113′ are formed of silicon oxide, a portion of the lower structure 110 adjacent to the support patterns 113′ may be formed of silicon (e.g., polysilicon, single crystal silicon, or the like). In another example, when the support patterns 113′ are formed of a semiconductor material such as silicon, silicon germanium, or the like, a portion of the lower structure 110 adjacent to the support patterns 113′ may be formed of silicon oxide or silicon nitride. An interface 110b between the first gate dielectric structure 128 and the lower structure 110 may be disposed below an interface 110a between the support patterns 113′ and the lower structure 110. Thus, in an upper surface of the lower structure 110, a portion in contact with the support patterns 113′ may be disposed above a portion in contact with the first gate dielectric structure 128.

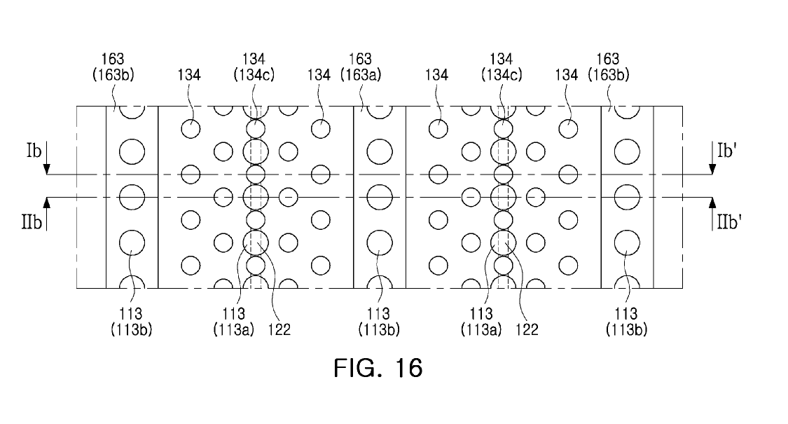

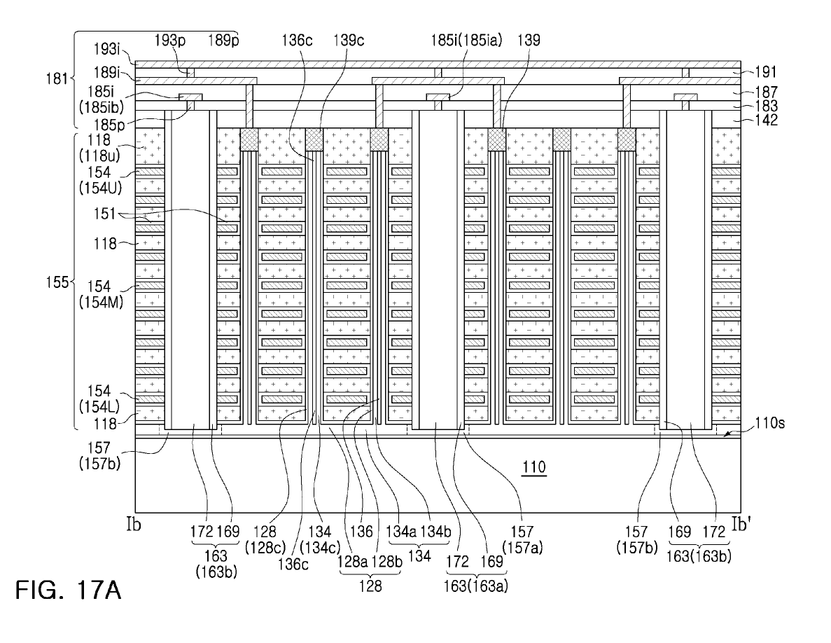

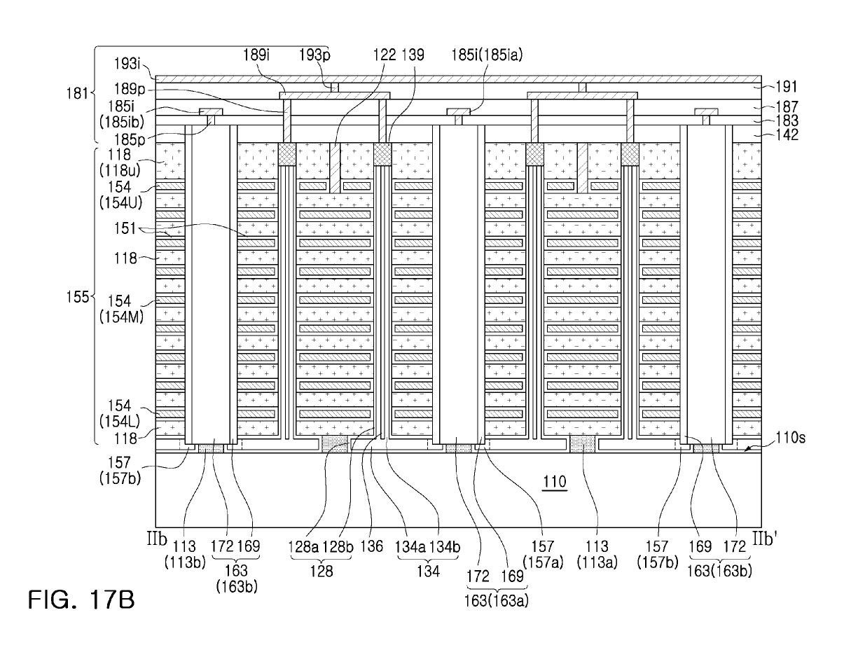

As described previously with reference to FIGS. 2, 3A, 3B, 4A, 4B, 5, and 6, the first support patterns 113a of the support patterns 113 may overlap a structure, including the additional channel layer 134c, the additional gate dielectric 128c, the additional core layer 136c, and the additional pad layer 139c. However, a technical idea of application is not limited thereto. Hereinafter, a modified example of the the first support patterns 113a will be described with reference to FIGS. 16, 17A, and 17B. FIG. 16 is a plan view illustrating a three-dimensional semiconductor device according to an example embodiment, FIG. 17A is a cross-sectional view illustrating a region taken along line Ib-Ib′ of FIG. 16, and FIG. 17B is a cross-sectional view illustrating a region taken along line IIb-IIb′ of FIG. 16.

As described previously with reference to FIGS. 16, 17A, and 17B, the first support patterns 113a of the support patterns 113, described above, may not overlap a structure, including the additional channel layer 134c, the additional gate dielectric 128c, the additional core layer 136c, and the additional pad layer 139c. Thus, the additional gate dielectric 128c may be modified to be connected continuously to the lower portion 128a of the first gate dielectric structure 128, while the additional channel layer 134c may be modified to be connected continuously to the horizontal portion 134a of the channel structure 134. The additional channel layer 134c may be formed integrally with the horizontal portion 134a of the channel structure 134. The additional gate dielectric 128c and the lower portion 128a of the first gate dielectric structure 128 may be integrally formed, while the additional channel layer 134c and the horizontal portion 134a of the channel structure 134 may be integrally formed.

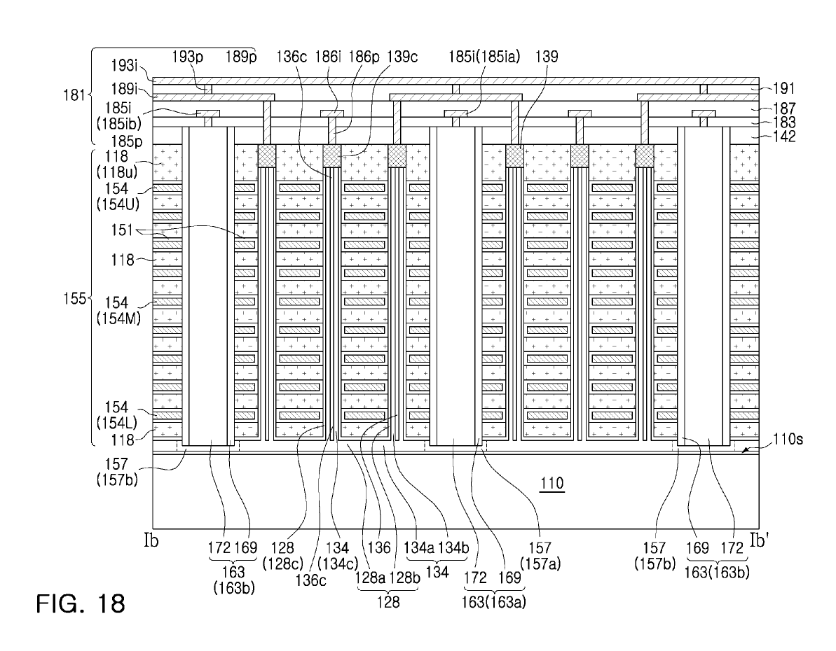

As described previously, the first impurity region 157a and the second impurity region 157b may have different conductivity. However, a technical idea of the application is not limited thereto. Next, referring to FIGS. 16 and 18, an example in which the first impurity region 157a and the second impurity region 157b are the same conductivity will be described. FIG. 18 is a cross-sectional view illustrating a region taken along line Ib-Ib′ of FIG. 16.

Referring to FIGS. 16 and 18, the first impurity region 157a and the second impurity region 157b, described above, may have the same conductivity, for example, an n-type conductivity. The body wiring 186i, capable of applying a body voltage to the channel structure 134, may be disposed on the additional pad layer 139c. The body wiring 186i may be electrically connected to the additional pad layer 139c, through a body plug 186p between the additional pad layer 139c and the body wiring 186i.

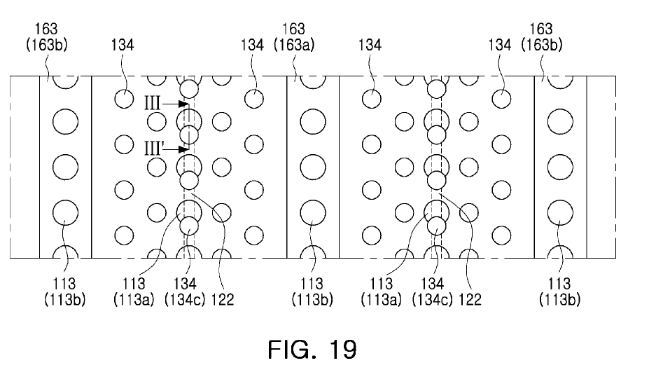

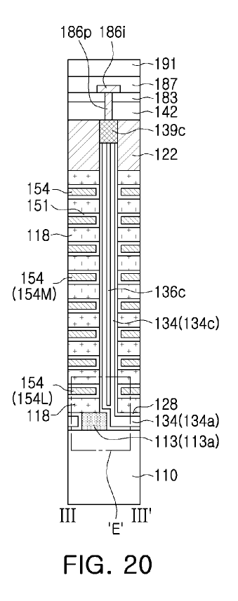

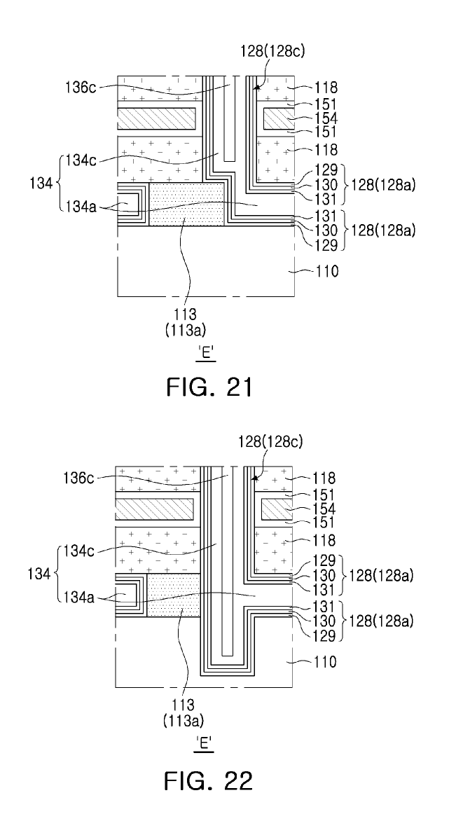

Next, a modified example of the the first support patterns 113a will be described with reference to FIGS. 19, 20, and 21. FIG. 19 is a plan view illustrating a three-dimensional semiconductor device according to an example embodiment, FIG. 20 is a cross-sectional view illustrating a region taken along line III-III′ of FIG. 19, and FIG. 21 is a partially enlarged view enlarging a portion indicated by ‘E’ of FIG. 20.

Referring to FIGS. 19, 20, and 21, the first support patterns 113a of the support patterns 113, described previously, may partially overlap a structure, including the additional channel layer 134c, the additional gate dielectric 128c, the additional core layer 136c, and the additional pad layer 139c. The additional gate dielectric 128c may be modified to be connected continuously to the lower portion 128a of the first gate dielectric structure 128, while the additional channel layer 134c may be modified to be connected continuously to the horizontal portion 134a of the channel structure 134. The additional channel layer 134c may be formed to have an integral structure with the horizontal portion 134a of the channel structure 134.

Next, referring to FIG. 22, an exemplary example of the additional channel layer 134c, the additional gate dielectric 128c, and the additional core layer 136c will be described. FIG. 22 is a partially enlarged view enlarging a portion indicated by ‘E’ of FIG. 20.

Referring to FIG. 22, in an exemplary example, the additional channel layer 134c, the additional gate dielectric 128c, and the additional core layer 136c may pass through the support patterns 113 to be extended into the lower structure 110.

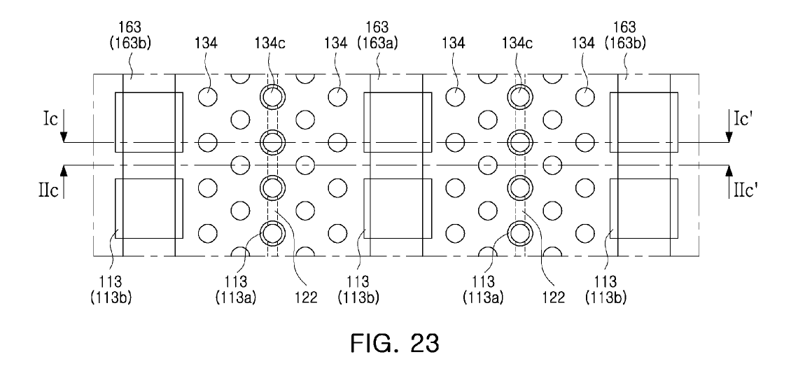

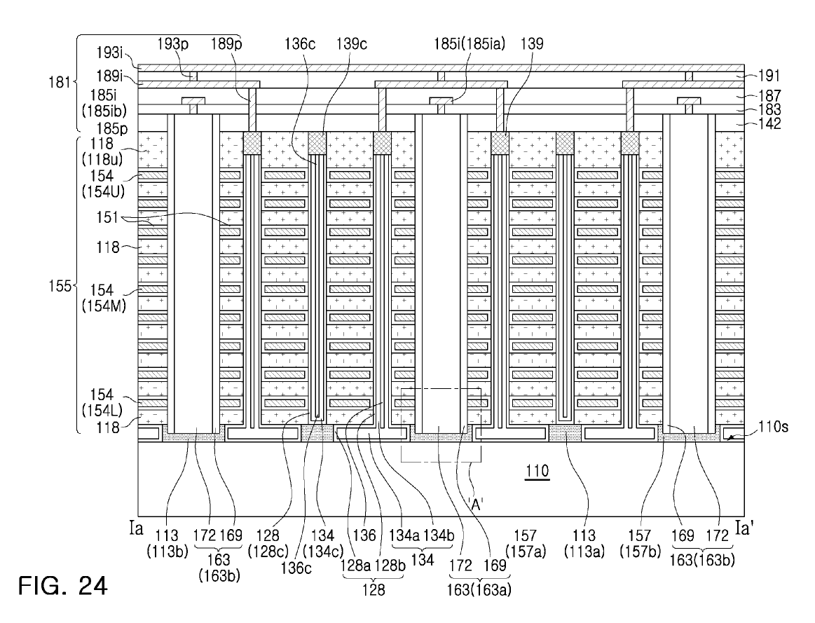

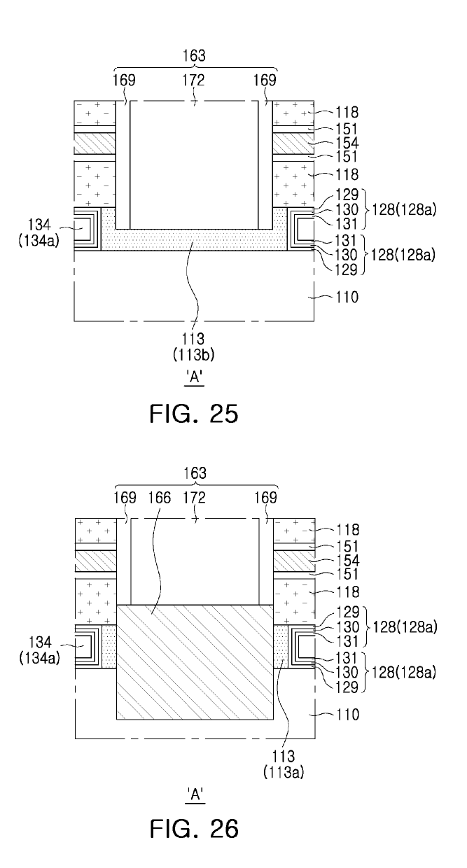

Next, a modified example of the the second support patterns 113b of the support patterns 113 will be described with reference to FIGS. 23, 24, and 25. FIG. 23 is a plan view illustrating a three-dimensional semiconductor device according to an example embodiment, FIG. 24 is a cross-sectional view illustrating a region taken along line Ic-Ic′ of FIG. 23, and FIG. 25 is a partially enlarged view enlarging a portion indicated by ‘A’ of FIG. 24. In FIG. 23, a cross-sectional structure of a region taken along line IIc-IIc′ may be the same as a cross-sectional structure of FIG. 3B illustrating a region taken along line IIa-IIa′ of FIG. 2. Here, this will be described together with FIG. 3B.

Referring to FIG. 3B together with FIGS. 23, 24, and 25, the second support patterns 113b of the support patterns 113 may be modified to have a width greater than a width of the line structures 163. The second support patterns 113b, described above, may have a width greater than that of the first support patterns 113a.

In one example, the line structures 163 may be disposed on the second support patterns 113b. However, a technical idea of the application is not limited thereto. A modified example of the line structures 163 will be described with reference to FIG. 26. FIG. 26 is a view illustrating to describe a portion modified from FIG. 25, in which a portion indicated by ‘A’ of FIG. 24 is enlarged. Thus, FIG. 26 illustrates a modified portion of the line structures 163 in a position corresponding to a portion indicated by ‘A’ of FIG. 24.

Referring to FIG. 26, the line structures 163 may include a lower material layer 166 passing through the second support patterns 113b described with reference to FIGS. 24 and 25, and extended into the lower structure 110, a conductive pattern 172 disposed on the lower material layer 166, and insulating spacers 169 on side surfaces of the conductive pattern 172. The lower material layer 166 may be a material such as silicon, silicon-germanium, or the like, as described with reference to FIGS. 10A and 10B. For example, the lower material layer 166 may be silicon formed using a selective epitaxial growth (SEG) process.

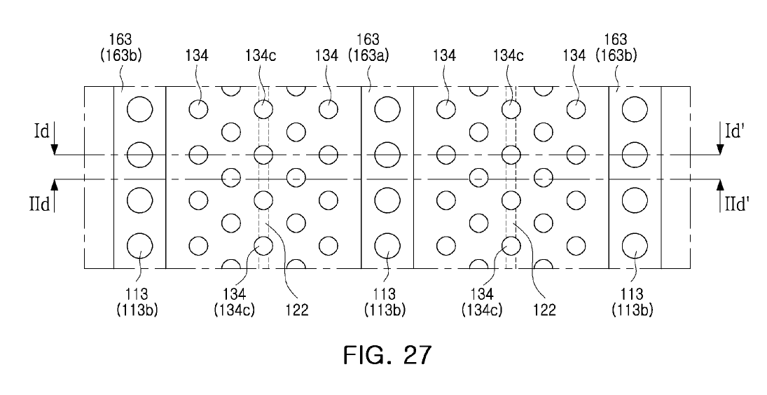

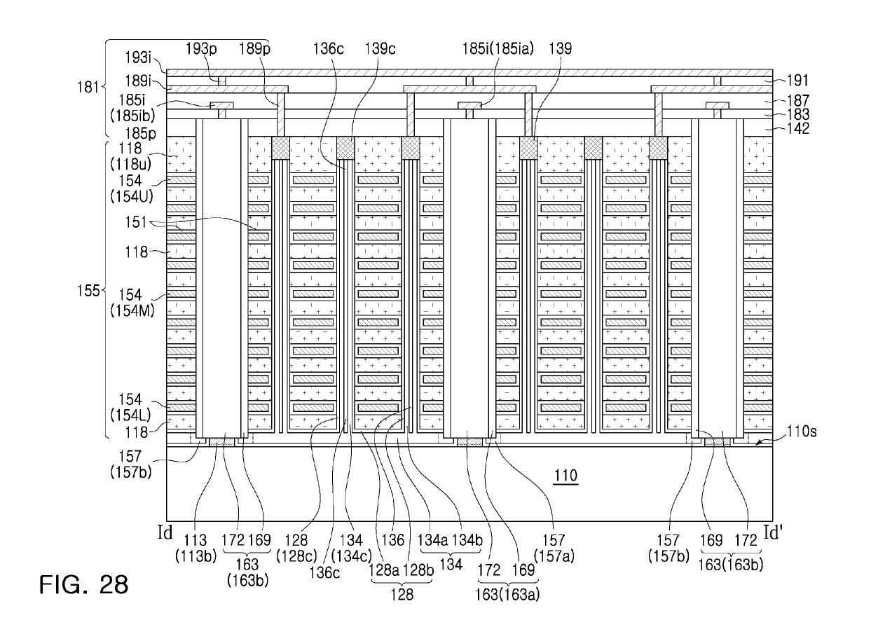

Next, a modified example of the the support patterns 113 will be described with reference to FIGS. 27 and 28. FIG. 27 is a plan view illustrating a three-dimensional semiconductor device according to an example embodiment, while FIG. 28 is a cross-sectional view illustrating a region taken along line Id-Id′ of FIG. 27. In FIG. 27, a cross-sectional structure of a region taken along line IId-IId′ may be the same as a cross-sectional structure of FIG. 3B illustrating a region taken along line IIa-IIa′ of FIG. 2. A cross-sectional structure of a region taken along line IId-IId′ of FIG. 27 may be the same as a cross-sectional structure of FIG. 3B. Here, this will be described together with FIG. 3B.

Referring to FIG. 3B together with FIGS. 27 and 28, the support patterns 113 may be modified not to overlap the stacked structure 155. Thus, the support patterns 113 may include the second support patterns 113b, while the second support patterns 113b may be disposed below the line structures 163. The additional channel layer 134c, described previously, may be modified to be integrally connected to the horizontal portion 134a of the channel structure 134. The additional gate dielectric 128c, described previously, may be modified to be integrally connected to the lower portion 128a of the first gate dielectric structure 128.

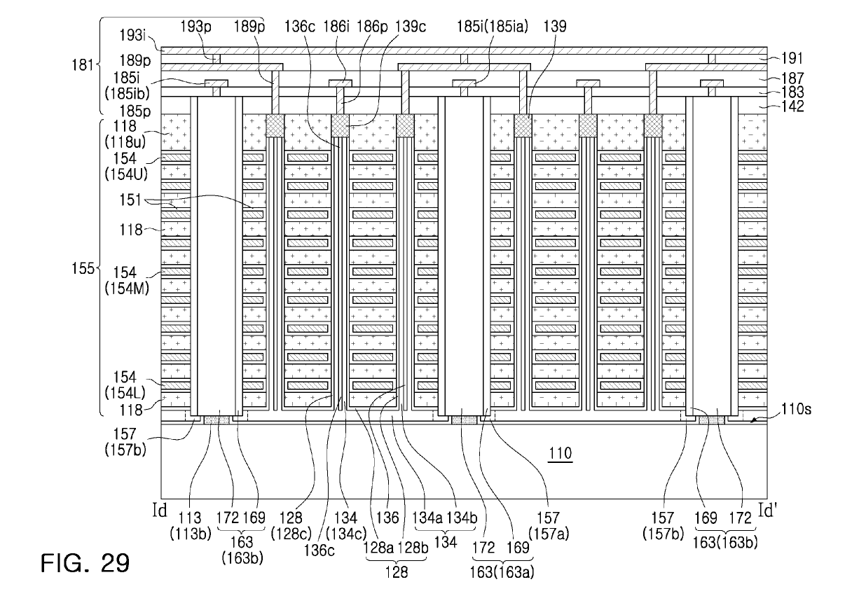

In a modified example, referring to FIG. 29, on the additional pad layer 139c disposed on the additional channel layer 134c, the body wiring 186i and the body plug 186p, the same as those described with reference to FIG. 18, may be disposed thereon. Here, FIG. 29 is a cross-sectional view illustrating a region taken along line Id-Id′ of FIG. 27.

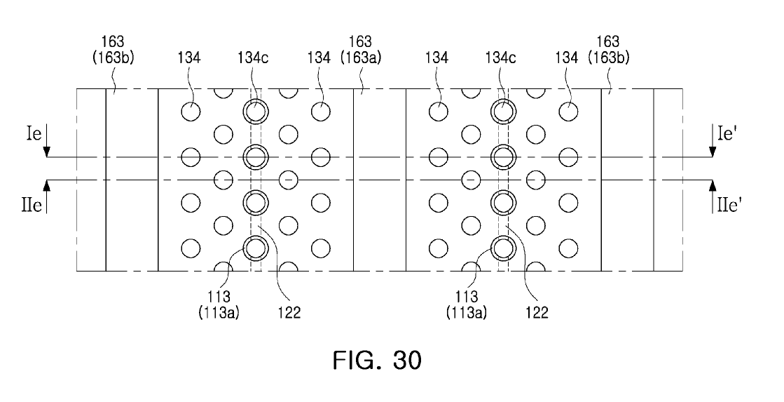

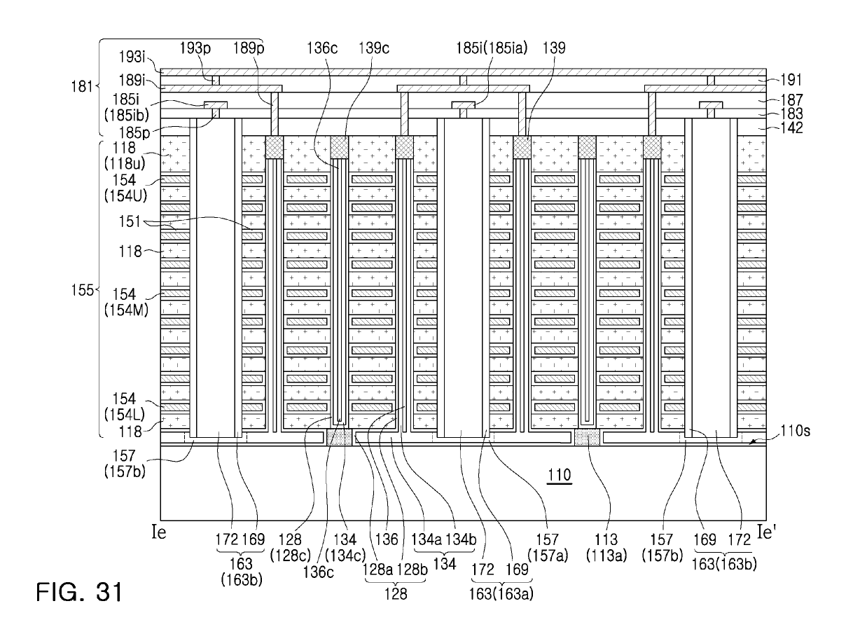

Next, a modified example of the the support patterns 113 will be described with reference to FIGS. 30 and 31. FIG. 30 is a plan view illustrating a three-dimensional semiconductor device according to an example embodiment, while FIG. 31 is a cross-sectional view illustrating a region taken along line Ie-Ie′ of FIG. 30. In FIG. 30, a cross-sectional structure of a region taken along line IIe-IIe′ may be the same as a cross-sectional structure of FIG. 3B illustrating a region taken along line IIa-IIa′ of FIG. 2. A cross-sectional structure of a region taken along line IIe-IIe′ of FIG. 30 may be the same as a cross-sectional structure of FIG. 3B. Here, this will be described together with FIG. 3B.

Referring to FIG. 3B together with FIGS. 30 and 31, the support patterns 113 may be modified not to overlap the line structures 163. Thus, the support patterns 113 may include the first support patterns 113a. The additional channel layer 134c, the additional gate dielectric 128c, the additional core layer 136c, and the additional pad layer 139c, described previously, may be disposed on the first support patterns 113a, as illustrated with reference to FIGS. 2 and 3A.

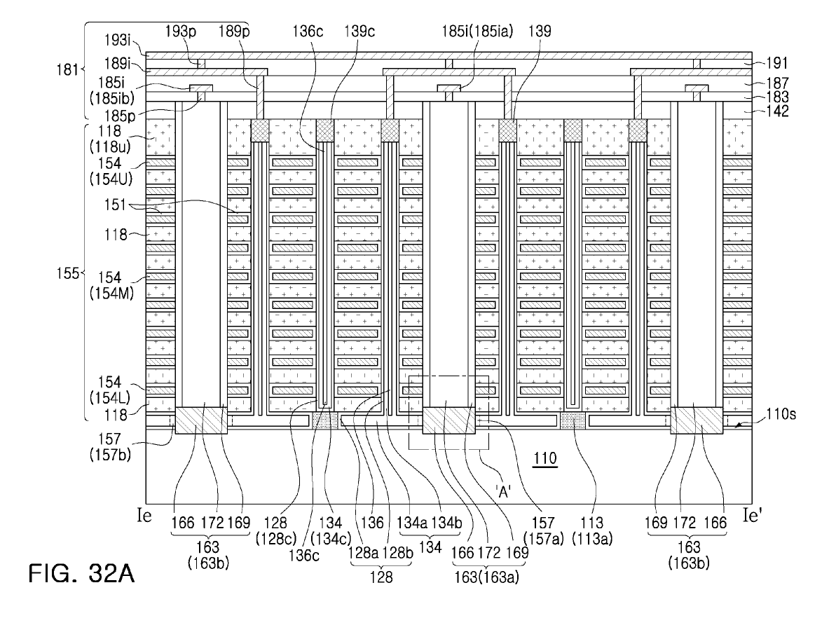

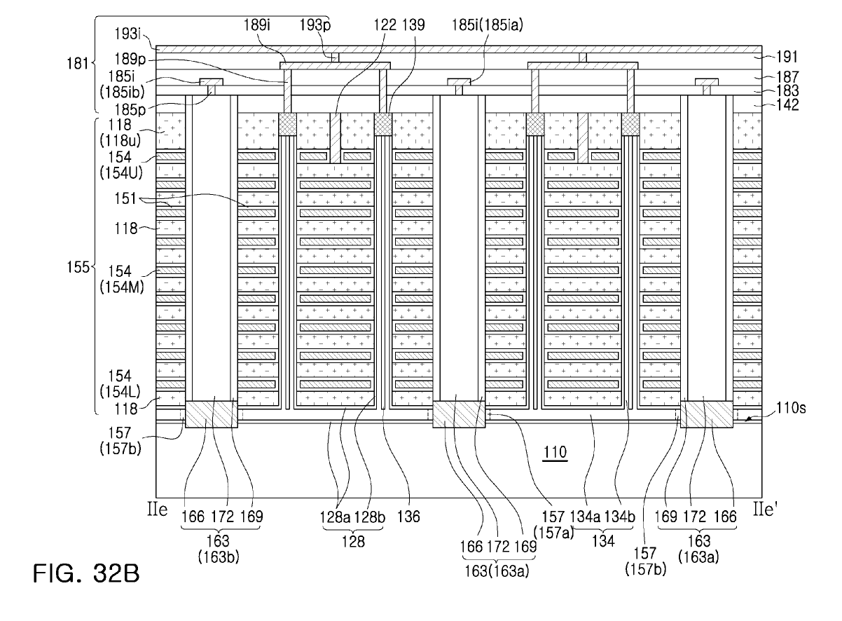

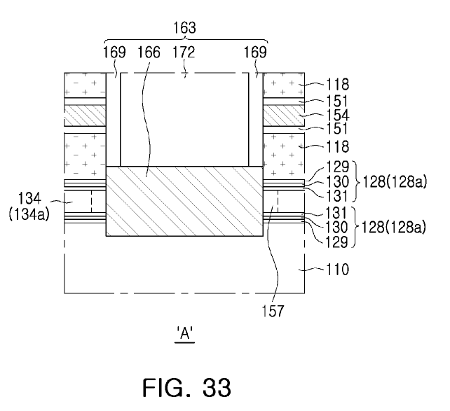

In one example, the horizontal portion 134a of the channel structure 134 is disposed below the stacked structure 155 and may be extended to a lower portion of the line structures 163 from a lower portion of the stacked structure 155. However, a technical idea of the application is not limited thereto. A modified example of the horizontal portion 134a of the channel structure 134 and the line structures 163 will be described with reference to FIGS. 32A, 32B, and 33. FIG. 32A is a cross-sectional view illustrating a region taken along line Ie-Ie′ of FIG. 30, FIG. 32B is a cross-sectional view illustrating a region taken along line IIe-IIe′ of FIG. 30, and FIG. 33 is a partially enlarged view enlarging a portion indicated by ‘A’ of FIG. 32A.

Referring to FIGS. 30, 32A, 32B, and 33, the line structures 163 may pass through the horizontal portion 134a of the channel structure 134, and the lower portion 128a of the first gate dielectric structure 128 to be extended into the lower structure 110. The line structures 163 may include a lower material layer 166 in contact with the horizontal portion 134a of the channel structure 134, and the lower portion 128a of the first gate dielectric structure 128, a conductive pattern 172 disposed on the lower material layer 166, and insulating spacers 169. The conductive pattern 172 and the insulating spacers 169 may be in contact with the lower material layer 166, and may be spaced apart from the horizontal portion 134a of the channel structure 134. The lower material layer 166 may be a material such as silicon, silicon-germanium, or the like. For example, the lower material layer 166 may be silicon formed using a selective epitaxial growth (SEG) process.

In one example, the lower material layer 166 may include doped silicon. An impurity region 157 may be formed in the horizontal portion 134a of the channel structure 134 adjacent to the lower material layer 166.

In a modified example, the lower material layer 166 may include an intrinsic semiconductor material, and the impurity region 157 may be omitted.

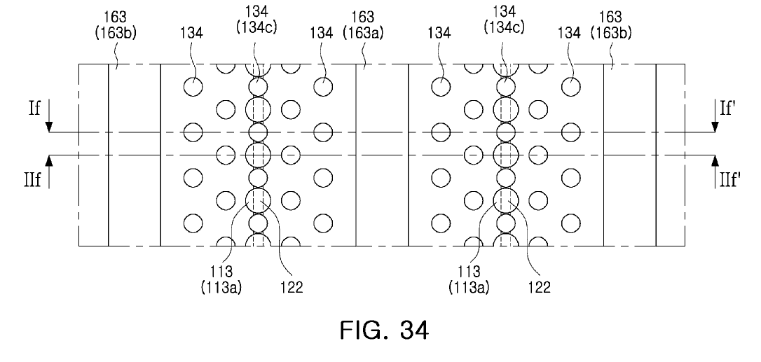

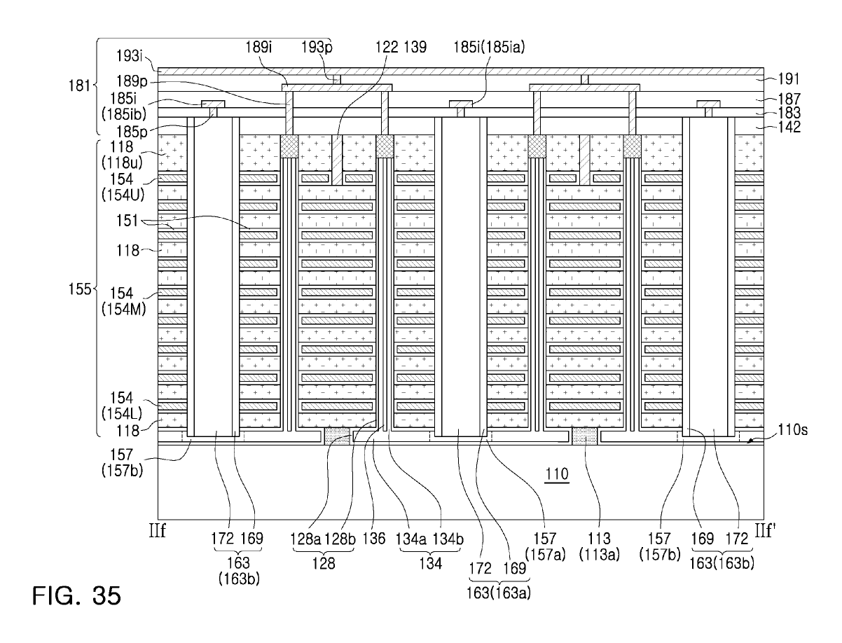

Next, a modified example of the the support patterns 113 will be described with reference to FIGS. 34 and 35. FIG. 34 is a plan view illustrating a three-dimensional semiconductor device according to an example embodiment, while FIG. 35 is a cross-sectional view illustrating a region taken along line IIf-IIf′ of FIG. 34. In FIG. 34, a cross-sectional structure of a region taken along line If-If′ may be the same as a cross-sectional structure of FIG. 3B illustrating a region taken along line IIa-IIa′ of FIG. 2. A cross-sectional structure of a region taken along line IIf-IIf′ of FIG. 34 may be the same as a cross-sectional structure of FIG. 3B. Here, this will be described together with FIG. 3B.

Referring to FIG. 3B together with FIGS. 34 and 35, the support patterns 113 may be modified not to overlap the line structures 163 but to overlap the stacked structure 155. Thus, the support patterns 113 may include the first support patterns 113a overlapping the stacked structure 155. The additional gate dielectric 128c, described previously, may be modified to be connected continuously to the lower portion 128a of the first gate dielectric structure 128, while the additional channel layer 134c may be modified to be connected continuously to the horizontal portion 134a of the channel structure 134.

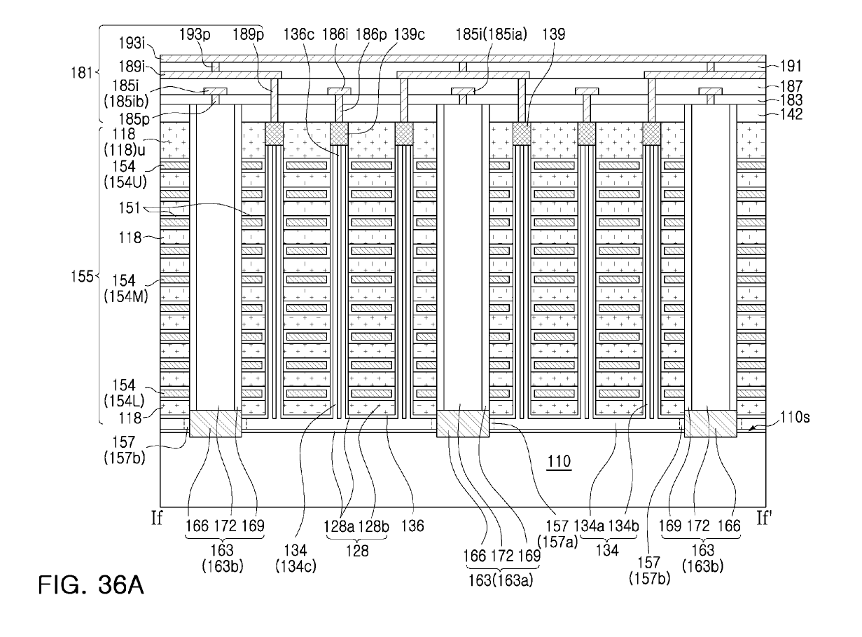

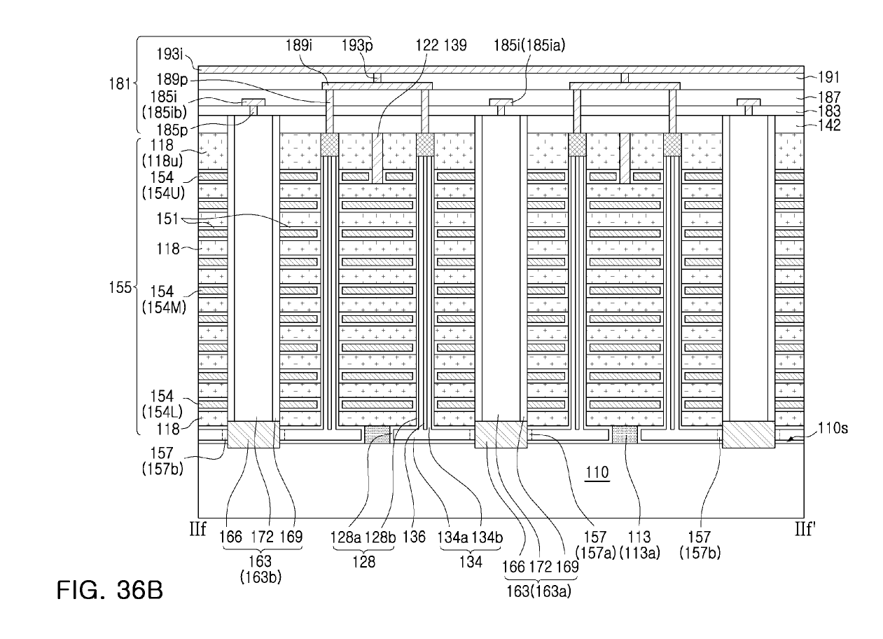

In one example, the horizontal portion 134a of the channel structure 134 is disposed below the stacked structure 155 and may be extended to a lower portion of the line structures 163 from a lower portion of the stacked structure 155. However, a technical idea of the application is not limited thereto. A modified example of the horizontal portion 134a of the channel structure 134 and the line structures 163 will be described with reference to FIGS. 34, 36A, and 36B. FIG. 36A is a cross-sectional view illustrating a region taken along line If-If′ of FIG. 34, while FIG. 36B is a cross-sectional view illustrating a region taken along line IIf-IIf′ of FIG. 34.

Referring to FIGS. 34, 36A, and 36B, the line structures 163 may pass through the horizontal portion 134a of the channel structure 134, and the lower portion 128a of the first gate dielectric structure 128 to be extended into the lower structure 110, as described with reference to FIGS. 32A and 32B. Thus, the line structures 163 may include a lower material layer 166 in contact with the horizontal portion 134a of the channel structure 134, and the lower portion 128a of the first gate dielectric structure 128, the conductive pattern 172 disposed on the lower material layer 166, and the insulating spacers 169, as described with reference to FIGS. 32A and 32B.

As described previously, below any one of the line structures 163, extended in any one direction, the support patterns 113 are arranged in a direction the same as a line direction of the line structures 163 and may be spaced apart from each other. However, a technical idea of the application is not limited to the shape of the support patterns 113, spaced apart from each other and arranged in any one direction. Hereinafter, a modified example of the support patterns 113 will be described.

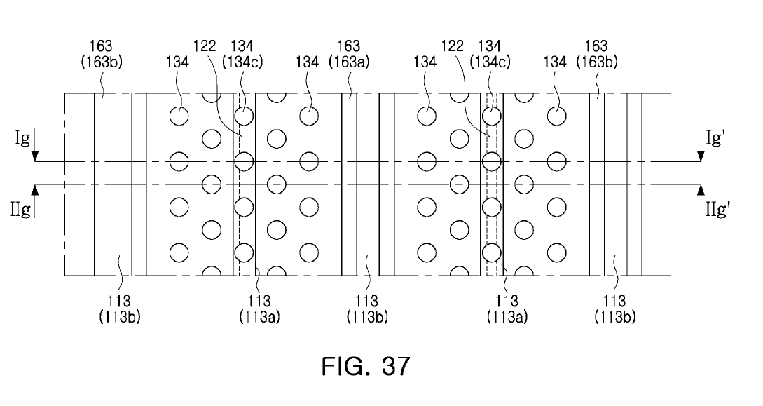

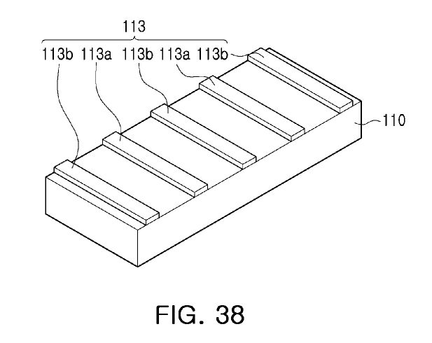

First, a modified example of the support patterns 113 will be described with reference to FIGS. 37 and 38. FIG. 37 is a plan view illustrating a three-dimensional semiconductor device according to an example embodiment, while FIG. 38 is a perspective view illustrating a modified shape of the support patterns 113. In FIG. 37, a cross-sectional structure taken along line Ig-Ig′ may be the same as a cross-sectional structure of FIG. 3A illustrating a region taken along line Ia-Ia′ of FIG. 2, while a cross-sectional structure taken along line IIg-IIg′ may be the same as a cross-sectional structure of FIG. 17B illustrating a region taken along line IIb-IIb′ of FIG. 16. Here, this will be described together with FIGS. 3A and 17B.

Referring to FIGS. 3A and 17B together with FIGS. 37 and 38, each of the support patterns 113 may be modified to be extended in a direction the same as a line direction of the line structures 163. The support patterns 113 may include a second support pattern 113b with a line shape overlapping the line structures 163 and a first support pattern 113a with a line shape overlapping the stacked structure 155.

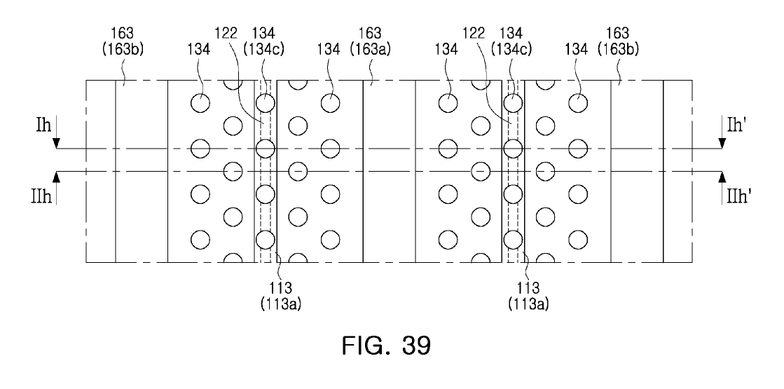

Next, referring to FIG. 39, a modified example of the support patterns 113 will be described. FIG. 39 is a plan view illustrating a modified example of a three-dimensional semiconductor device according to an example embodiment. In FIG. 39, a cross-sectional structure taken along line Ih-Ih′ may be the same as a cross-sectional structure of FIG. 31 illustrating a region taken along line Ie-Ie′ of FIG. 30, while a cross-sectional structure taken along line IIh-IIh′ may be the same as a cross-sectional structure of FIG. 35 illustrating a region taken along line IIf-IIf′ of FIG. 34. Here, this will be described together with FIGS. 31 and 35.

Referring to FIGS. 31 and 35 together with FIG. 39, the support patterns 113 may have a line shape not overlapping the line structures 163 but overlapping the stacked structure 155.

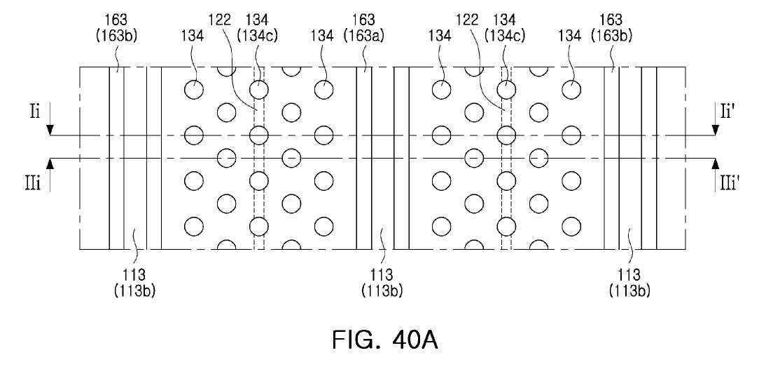

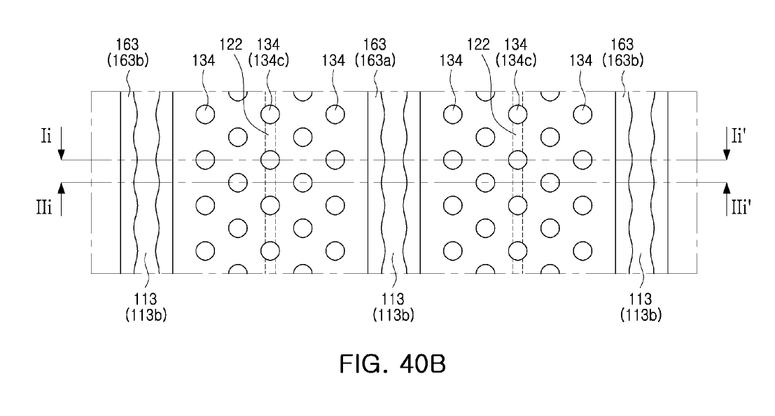

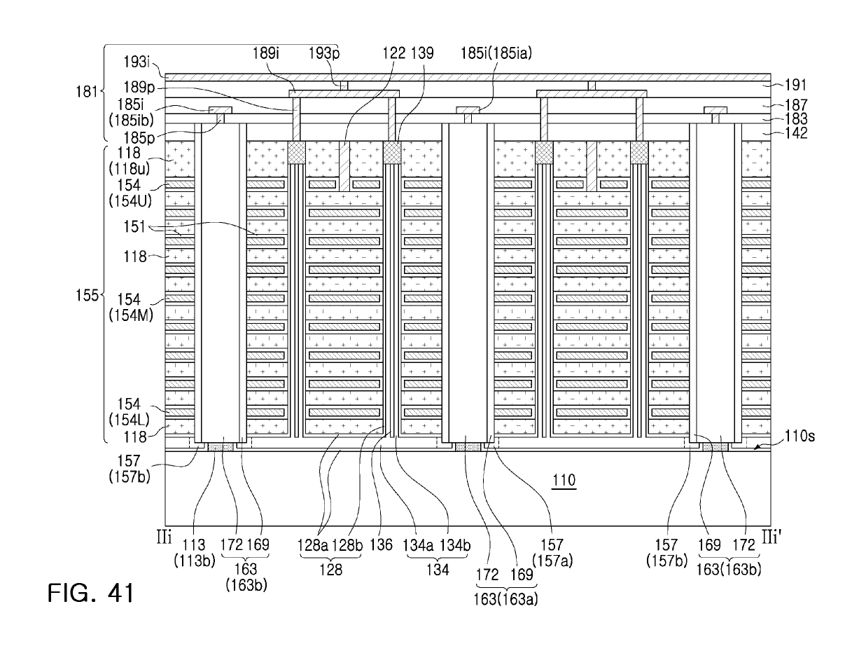

Next, referring to FIGS. 40A and 41, a modified example of the support patterns 113 will be described. FIG. 40A is a plan view illustrating a three-dimensional semiconductor device according to an example embodiment, while FIG. 41 is a cross-sectional view illustrating a region taken along line IIi-IIi′ of FIG. 40A. In FIG. 40A, a cross-sectional structure taken along line Ii-Ii′ may be the same as a cross-sectional structure of FIG. 28 illustrating a region taken along line Id-Id′ of FIG. 27. Here, this will be described together with FIG. 27.

Referring to FIGS. 40A and 41 together with FIG. 27, the support patterns 113 may have a line shape not overlapping the stacked structure 155 but overlapping the line structures 163.

In a modified example, referring to FIG. 40B, the support patterns 113, not overlapping the stacked structure 155 but overlapping the line structures 163, may have a line shape extended in a direction the same as the line structures 163, and having a curved side surface. FIG. 40B is a plan view illustrating a modified example of the support patterns 113 of FIG. 40A.

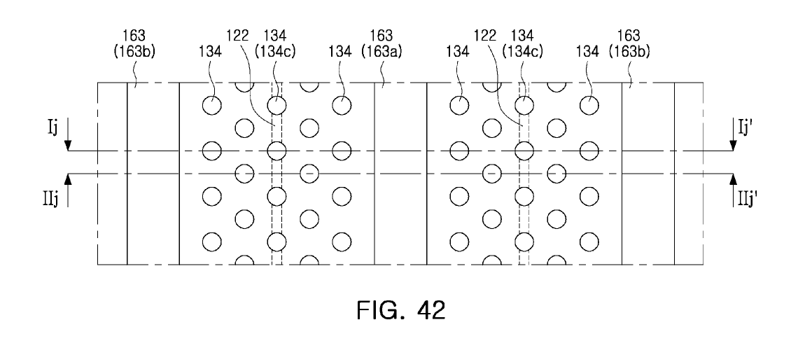

As described previously, a three-dimensional semiconductor device according to an example embodiment may include support patterns 113 described previously. However, a technical idea of the application is not limited thereto. For example, after the support patterns 113, described previously, are formed to be located below the line structures 163, before the line structures 163 are formed, the support patterns 113 located below the line structures 163 may be removed. Thus, in a final structure, the support patterns 113 may not be seen. The example, described above, will be described with reference to FIG. 42. In FIG. 42, a cross-sectional structure of a region taken along line Ij-Ij′ may be the same as a cross-sectional structure of FIG. 36A illustrating a region taken along line If-If′ of FIG. 34, while a cross-sectional structure of a region taken along line IIj-IIj′ may be the same as a cross-sectional structure of FIG. 32B illustrating a region taken along line IIe-IIe′ of FIG. 30. This will be described with reference to FIGS. 36A and 32B.

Referring to FIGS. 36A and 32B together with FIG. 42, the line structures 163 may pass through the horizontal portion 134a of the channel structure 134, and the lower portion 128a of the first gate dielectric structure 128 to be extended into the lower structure 110, as described with reference to FIGS. 36A and 32B. Thus, the line structures 163 may include the lower material layer 166 in contact with the horizontal portion 134a of the channel structure 134, and the lower portion 128a of the first gate dielectric structure 128, the conductive pattern 172 disposed on the lower material layer 166, and the insulating spacers 169, as described with reference to FIGS. 36A and 32B.

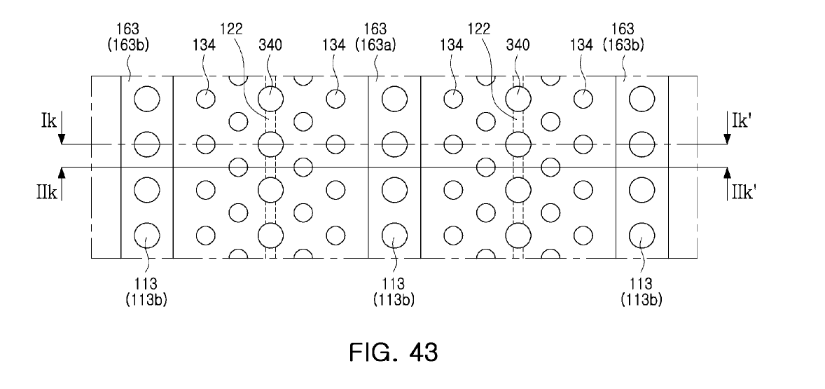

As described previously, the three-dimensional semiconductor device according to an example embodiment may include impurity regions 157 disposed in the horizontal portion 134a of the channel structure 134 adjacent to the line structures 163. Hereinafter, an exemplary example, in which, when the impurity regions 157 have the same conductivity, for example, an n-type conductivity, a body voltage may be applied to the channel structure 134 opposing the gate electrodes 154, will be described with reference to FIGS. 43 to 48.

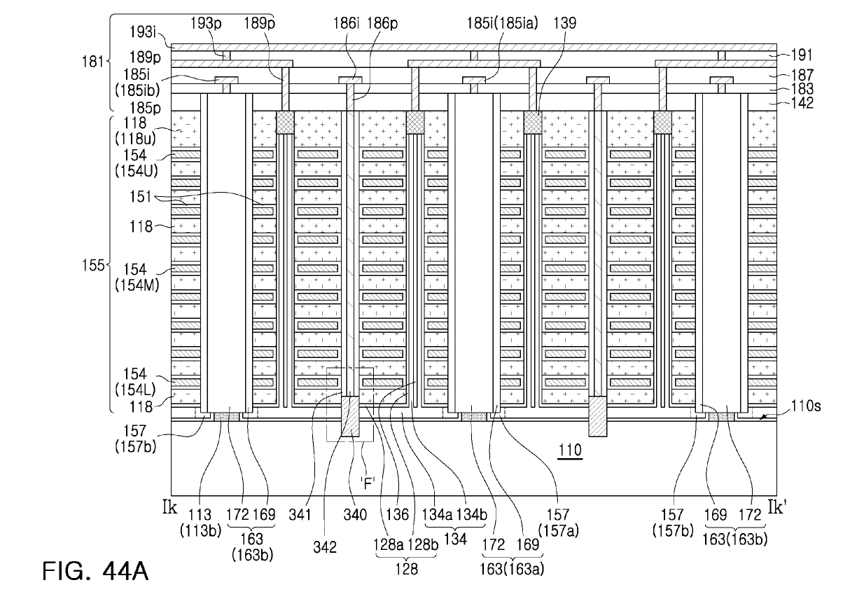

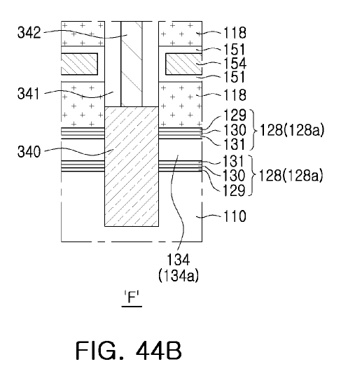

First, referring to FIGS. 43, 44A, and 44B, an exemplary example of a three-dimensional semiconductor device according to an example embodiment will be described. FIG. 43 is a plan view illustrating an exemplary example of a three-dimensional semiconductor device according to an example embodiment, FIG. 44A is a cross-sectional view illustrating a region taken along line Ik-Ik′ of FIG. 43, and FIG. 44B is a partially enlarged view enlarging a portion indicated by ‘F’ of FIG. 44A. In FIG. 43, a cross-sectional structure of a region taken along line IIk-IIk′ may be the same as a cross-sectional structure of FIG. 3B illustrating a region taken along line IIa-IIa′ of FIG. 2. Here, this will be described together with FIG. 3B.

Referring to FIG. 3B together with FIGS. 43, 44A, and 44B, the support patterns 113 may overlap the line structures 163. The line structures 163 may include a first line structure 163a and a second line structure 163b, spaced apart from each other and in parallel to each other as described previously. Body connection patterns 340, disposed between the first line structure 163a and the second line structure 163b, passing through the horizontal portion 134a of the channel structure 134 and the lower portion 128a of the first gate dielectric structure 128, and extended into the lower structure 110, may be provided. The body connection patterns 340 may be in contact with the horizontal portion 134a of the channel structure 134 and the lower portion 128a of the first gate dielectric structure 128.

In one example, the body connection patterns 340 may include a semiconductor material having a p-type conductivity, for example, silicon or silicon-germanium. For example, the body connection patterns 340 may be silicon formed using a selective epitaxial growth (SEG) process.

In a modified example, the body connection patterns 340 may include an intrinsic semiconductor material.

On the body connection patterns 340, body contact plugs 342, passing through the stacked structure 155, and insulating patterns 341, surrounding a side surface of the body contact plugs 342, may be provided. The body contact plugs 342 may include a conductive material.

The body wiring 186i, capable of applying a body voltage to the channel structure 134, may be disposed on the body contact plugs 342. A body plug 186p may be disposed between the body contact plugs 342 and the body wiring 186i. The body wiring 186i may apply a voltage to the channel structure 134 through the body plug 186p, the body contact plugs 342, and the body connection patterns 340.

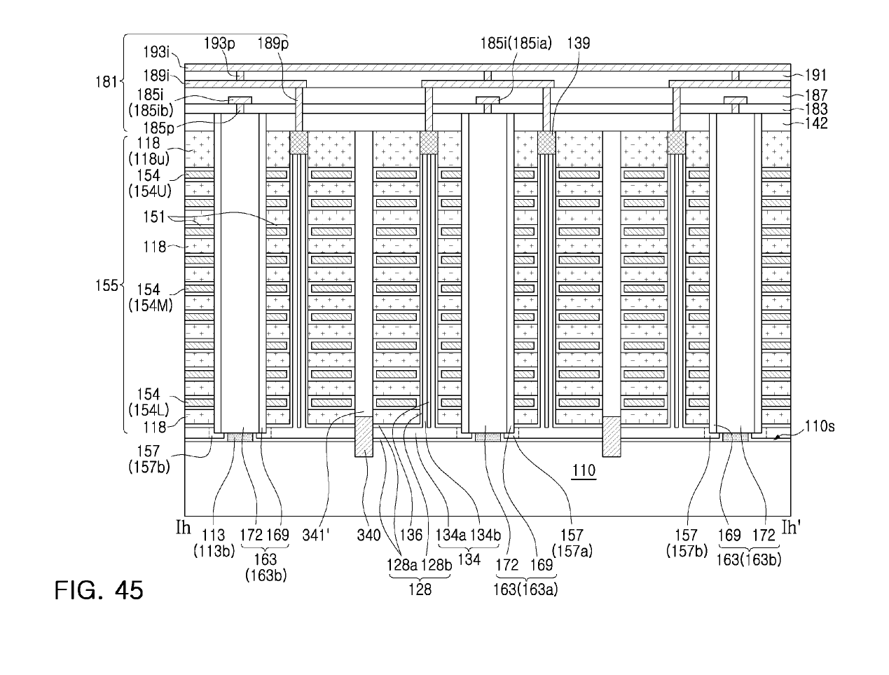

In a modified example, referring to FIG. 45, insulating patterns 341′, covering an upper surface of the body connection patterns 340 while passing through the stacked structure 155, may be disposed on the body connection patterns 340, and a body voltage may be applied to the channel structure 134 through the lower structure 110 and the body connection patterns 340. Here, the lower structure 110 may be a p-type semiconductor substrate. FIG. 45 is a cross-sectional view illustrating a region taken along line Ik-Ik′ of FIG. 43 to describe a modified example, in which a body voltage may be applied to the channel structure 134.

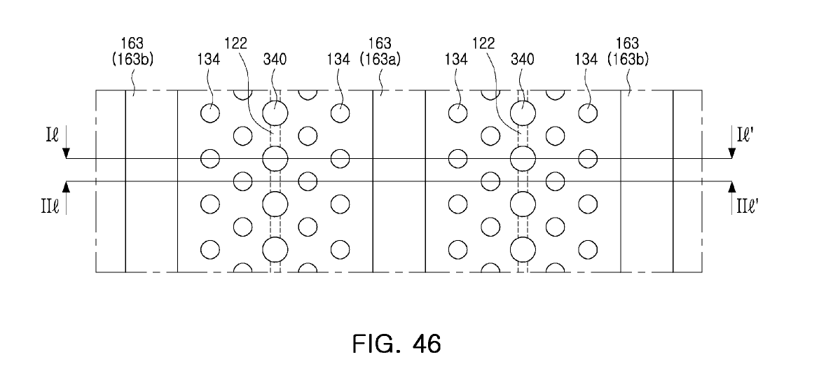

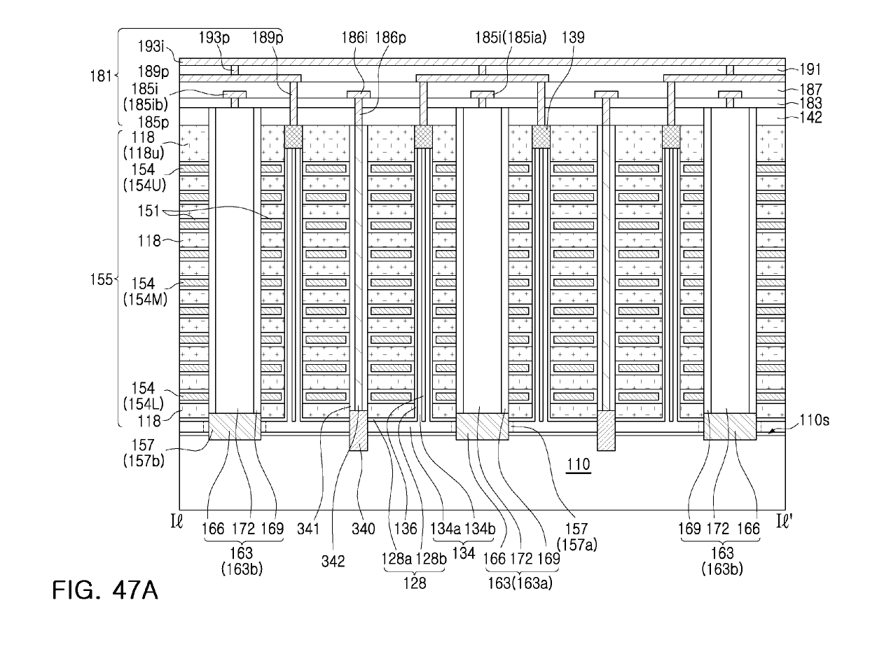

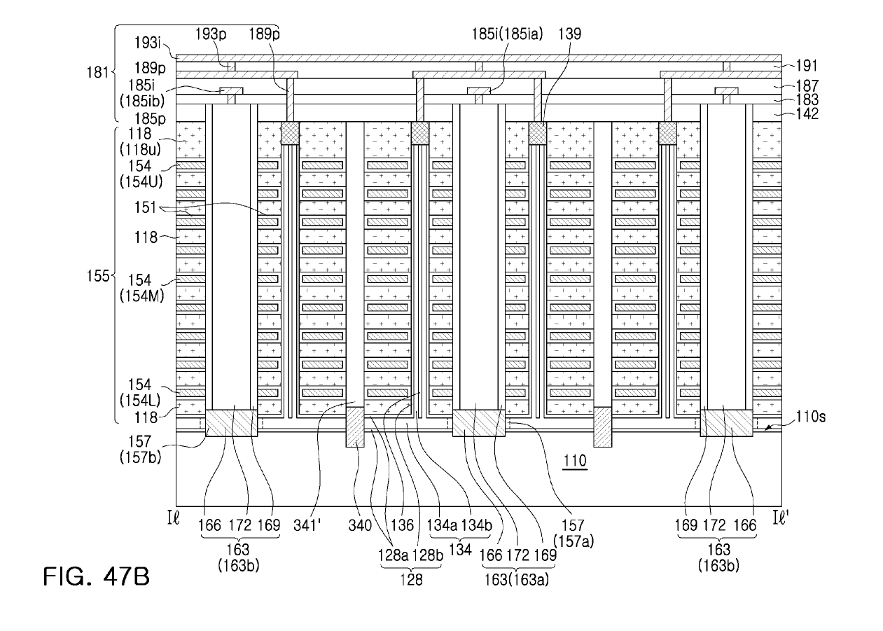

Next, referring to FIGS. 46 and 47A, an exemplary example of a three-dimensional semiconductor device according to an example embodiment will be described. FIG. 46 is a plan view illustrating an exemplary example of a three-dimensional semiconductor device according to an example embodiment, and FIG. 47A is a cross-sectional view illustrating a region taken along line Il-Il′ of FIG. 46. In FIG. 46, a cross-sectional structure of a region taken along line IIl-IIl′ may be the same as a cross-sectional structure of FIG. 32B illustrating a region taken along line IIe-IIe′ of FIG. 30. Here, this will be described together with FIG. 32B.

Referring to FIG. 32B together with FIGS. 46 and 47B, the line structures 163 may pass through the horizontal portion 134a of the channel structure 134, and the lower portion 128a of the first gate dielectric structure 128 to be extended into the lower structure 110, as described with reference to FIGS. 32A and 32B. Moreover, the line structures 163 may include the lower material layer 166 in contact with the horizontal portion 134a of the channel structure 134, and the lower portion 128a of the first gate dielectric structure 128, the conductive pattern 172 disposed on the lower material layer 166, and the insulating spacers 169.

As described with reference to FIGS. 44A and 44B, the body connection patterns 340 capable of applying a body voltage to the channel structure 134 through the body wiring 186i may be provided. Here, the body contact plugs 342 and the insulating patterns 341, the same as those described with reference to FIGS. 44A and 44B, may be disposed on the body connection patterns 340.

In a modified example, referring to FIG. 47B, as described with reference to FIG. 45, the body connection patterns 340 capable of applying a body voltage to the channel structure 134 through the lower structure 110 may be provided. Here, insulating patterns 341′ covering an entirety of an upper surface of the channel structure 134 may be provided. FIG. 47B is a cross-sectional view illustrating a region taken along line Il-Il′ of FIG. 46.

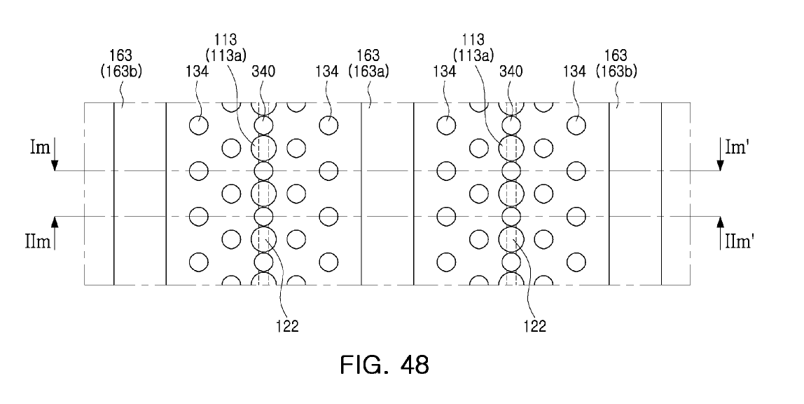

Next, referring to FIG. 48, an exemplary example of a three-dimensional semiconductor device according to an example embodiment will be described. FIG. 48 is a plan view illustrating an exemplary example of a three-dimensional semiconductor device according to an example embodiment. In FIG. 48, a cross-sectional structure of a region taken along line Im-Im′ may be the same as a cross-sectional structure of FIG. 47A or FIG. 47B illustrating a region taken along line Il-Il′ of FIG. 46, and a cross-sectional structure of a region taken along line IIm-IIm′ may be the same as a cross-sectional structure of FIG. 36B illustrating a region taken along line IIf-IIf′ of FIG. 34. This will be described with reference to one of FIGS. 47A and 47B, as well as FIG. 32B.

Referring to one of FIG. 47A and FIG. 47B, as well as FIG. 32B, together with FIG. 48, the support patterns 113, overlapping the stacked structure 155, may be provided. Between the support patterns 113, the body connection patterns 340 described with reference to FIG. 47A or the body connection patterns 340 described with reference to FIG. 47B may be disposed.

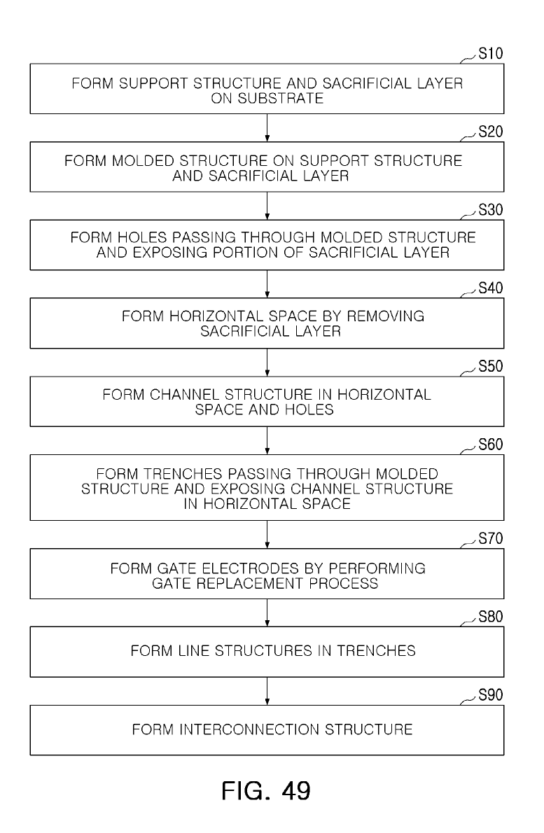

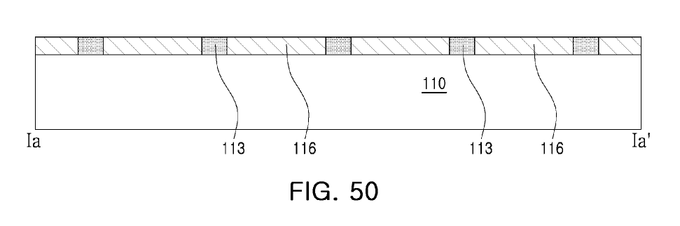

Next, referring to FIG. 2, as well as FIGS. 49 to 55, an exemplary example of a method for forming a three-dimensional semiconductor device according to an example embodiment will be described. FIG. 49 is a process flow chart illustrating an exemplary example of a method for forming a three-dimensional semiconductor device according to an example embodiment, while FIGS. 50 to 55 are cross-sectional views taken along line Ia-Ia′ of FIG. 2 to illustrate an exemplary example of a method for forming a three-dimensional semiconductor device according to an example embodiment.

Referring to FIGS. 2, 49, and 50, support patterns 113 and a sacrificial layer 116 may be formed on a lower structure 110 (S10). The lower structure 110 may include a semiconductor substrate. For example, the lower structure 110 may be a bulk silicon substrate. However, a technical idea of the application is not limited thereto. For example, the lower structure 110 may include a silicon substrate, a peripheral circuit on the silicon substrate, and a lower insulating structure disposed on the silicon substrate and covering the peripheral circuit. For example, the lower structure 110 may include the semiconductor substrate (102 of FIGS. 14A and 14B) and the peripheral circuit structure (108 of FIGS. 14A and 14B) on the semiconductor substrate 102, as illustrated in FIGS. 14A and 14B.

In one example, the support patterns 113 may include a semiconductor material, such as silicon, silicon germanium (SiGe), or the like. For example, the support patterns 113 may be silicon formed using a selective epitaxial growth (SEG) process or silicon formed using a deposition process.

In a modified example, the support patterns 113 may include an insulating material such as silicon oxide, or the like.

The sacrificial layer 116 may include a material having etch selectivity different from that of the support patterns 113. For example, when the support patterns 113 include silicon, the sacrificial layer 116 may be formed of silicon-germanium. When the support patterns 113 include silicon oxide, the sacrificial layer 116 may be formed of silicon or silicon-germanium.

In one example, forming the support patterns 113 and the sacrificial layer 116 may include forming the support patterns 113 on the lower structure 110, and forming the sacrificial layer 116 filling a gap between the support patterns 113.

In a modified example, forming the support patterns 113 and the sacrificial layer 116 may include forming the sacrificial layer 116 on the lower structure 110, forming an opening by patterning the sacrificial layer 116, and forming the support patterns 113 filling an opening of the sacrificial layer 116.

The support patterns 113 may be provided in the form of the support patterns described with reference to FIG. 13A, 13B, 14A, 14B, or 16.

Referring to FIGS. 2, 49, and 51, a molded structure 121 may be formed on the support patterns 113 and the sacrificial layer 116 (S20).

The molded structure 121 may include interlayer insulating layers 118 and 118u, spaced apart from each other in a direction perpendicular to an upper surface 110s of the lower structure 110 to be stacked, as well as gate replacement layers 120, formed between the interlayer insulating layers 118 and 118u. Here, the ‘gate replacement layer’ refers to a layer which is to be replaced with a gate in a subsequent process.

A top interlayer insulating layer 118u, among the interlayer insulating layers 118 and 118u, may be thicker than interlayer insulating layers 118 located relatively lower than the top interlayer insulating layer.

In one example, the interlayer insulating layers 118 and 118u may include silicon oxide, while the gate replacement layers 120 may include silicon nitride.

Holes 124, passing through the molded structure 121 and exposing a portion of the sacrificial layer 116, may be provided (S30).

In one example, the holes 124 may include channel holes 124c, exposing the sacrificial layer 116, and dummy holes 124d, exposing the support patterns 113.

In a modified example, according to the arrangement of the support patterns 113, the support patterns 113 may be partially exposed by the dummy holes 124d, or may not be exposed.

In a modified example, the holes 124 may be formed to expose the lower structure 110.

Referring to FIGS. 2, 49, and 52, the sacrificial layer 116 may be removed to form a horizontal space 125 (S40). The sacrificial layer 116 may be removed using an etching process. At least a portion of the holes 124 may be connected to the horizontal space 125.

In a modified example, while the sacrificial layer 116 is removed using an etching process, a portion of the lower structure 110, located below the sacrificial layer 116, may be etched. Thus, in the upper surface 110s of the lower structure 110, a portion, exposed by removing the sacrificial layer 116, may be located lower than a portion, located below the support patterns 113. While a portion of the lower structure 110 is etched and lowered, a lower structure 110, described with reference to FIGS. 15A and 15B, may be provided.

Referring to FIGS. 2, 49, and 53, a channel structure 134 may be formed in the horizontal space 125 and the holes 124 (S50).

Before the channel structure 134 is formed, first gate dielectric structures 128 may be conformally formed in inner walls of the horizontal space 125 and the holes 124. Forming the first gate dielectric structures 128 may include forming a blocking dielectric (129 of FIGS. 4A to 6), a data storage layer (130 of FIGS. 4A to 6), and a tunnel dielectric (131 of FIGS. 4A to 6), in sequence.

After the channel structure 134 is provided, core layers 136, partially filling the holes 124, may be provided. The pad layers 139, filling a remaining portion of the holes 124, may be formed on the core layer 136.

Among the first gate dielectric structures 128, a gate dielectric, formed on the support patterns 113, may be referred to as a dummy gate dielectric or an additional gate dielectric 128c.

Among the channel structure 134, a channel structure, formed on the support patterns 113, may be referred to as a dummy channel layer or an additional channel layer 134c.

The channel structure 134 may include a horizontal portion 134a, formed in the horizontal space 125, and a vertical portion 134b, formed in the channel holes 124c.

The first gate dielectric structures 128 may include a lower portion 128a, formed in the horizontal space 125, and upper portions 128b, formed in channel holes 124c.

Referring to FIGS. 2, 49, and 54, a first capping insulating layer 142 may be formed on the molded structure 121. The first capping insulating layer 142 may include silicon oxide.

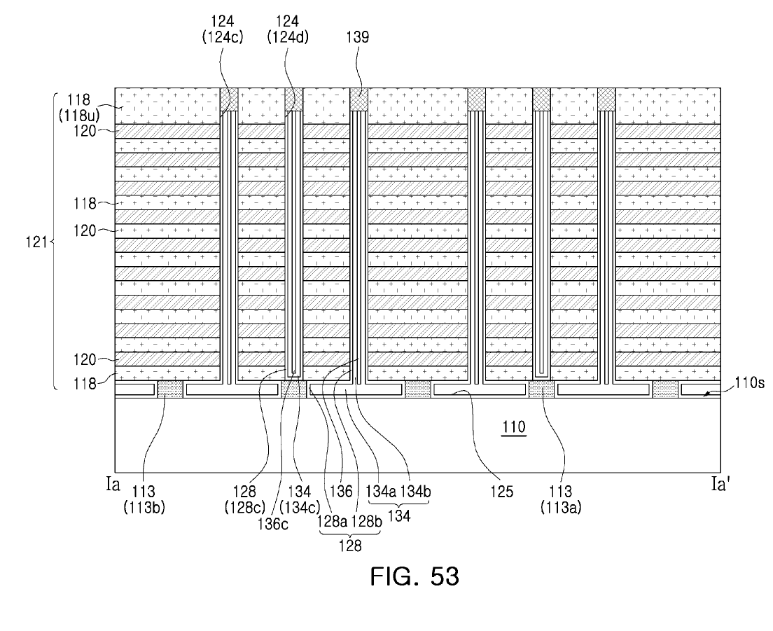

Trenches 145, passing through the molded structure 121, and exposing the channel structure 134 formed in the horizontal space (125 of FIG. 53), may be provided (S60). The trenches 145 may expose the horizontal portion 134a of the channel structure 134. The trenches 145 may pass through the molded structure 121, while passing through the first capping insulating layer 142. In one example, the trenches 145 may have a shape of lines parallel to each other.

The trenches 145 pass through the molded structure 121, and thus may expose the gate replacement layers 120 of the molded structure 121.

In one example, the trenches 145 may expose a portion 113b of the support patterns 113.

In a modified example, the trenches 145 may be extended into the lower structure 110 while passing through the horizontal portion 134a of the channel structure 134.

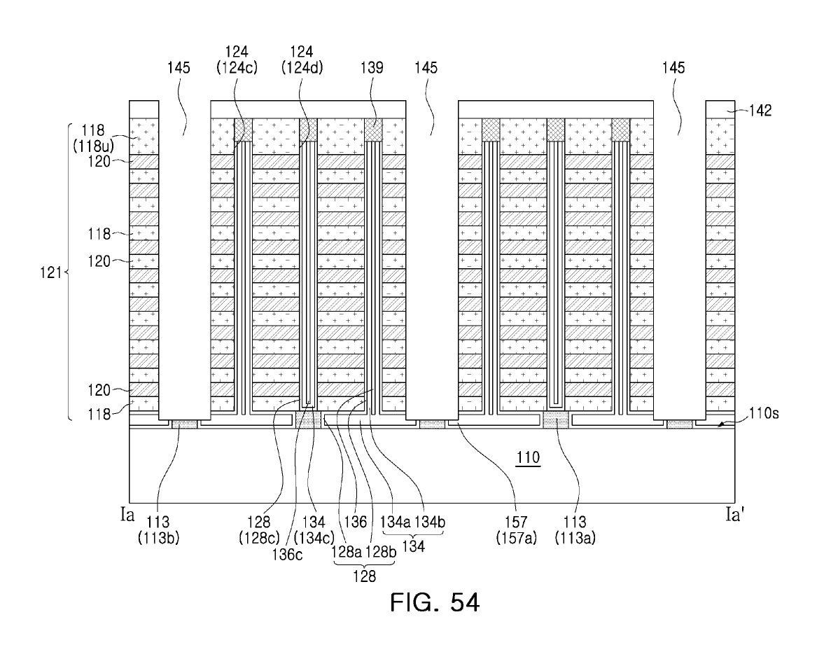

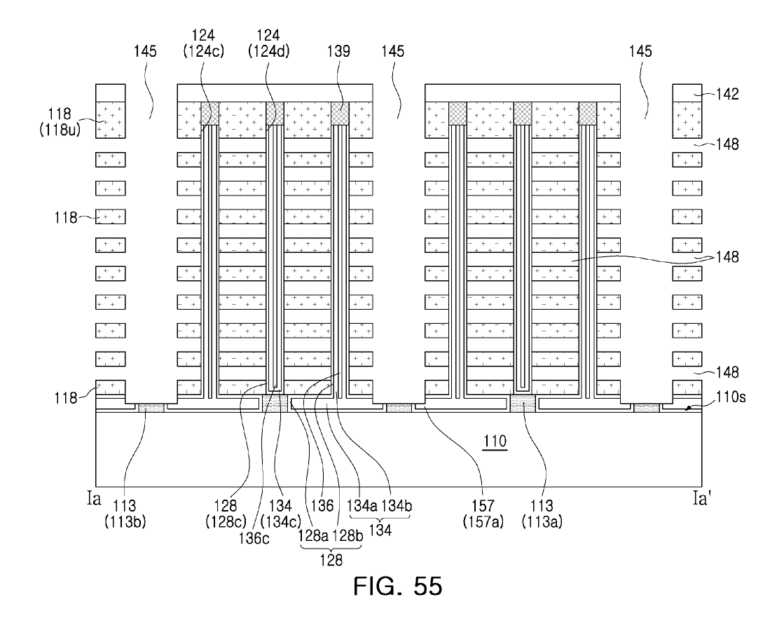

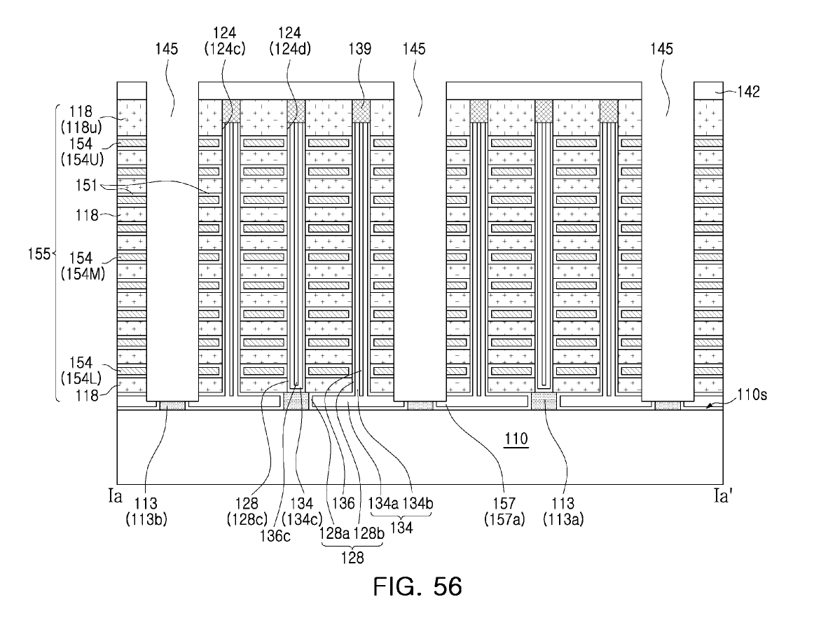

Referring to FIGS. 2, 49, 55, and 56, a gate replacement process may be performed to form gate electrodes (154 of FIG. 56) (S70). Performing the gate replacement process may include forming empty spaces (148 of FIG. 55) by removing the gate replacement layers (120 of FIG. 54) exposed by the trenches 145, and forming second gate dielectrics (151 of FIG. 56) and the gate electrodes (154 of FIG. 56) in the empty spaces (148 of FIG. 55) in sequence. The empty spaces (148 of FIG. 55) may expose the first gate dielectric structure 128.

The second gate dielectrics 151 may be interposed between the gate electrodes 154 and the first gate dielectric structures 128, and may be extended between the gate electrodes 154 and the interlayer insulating layers 118.

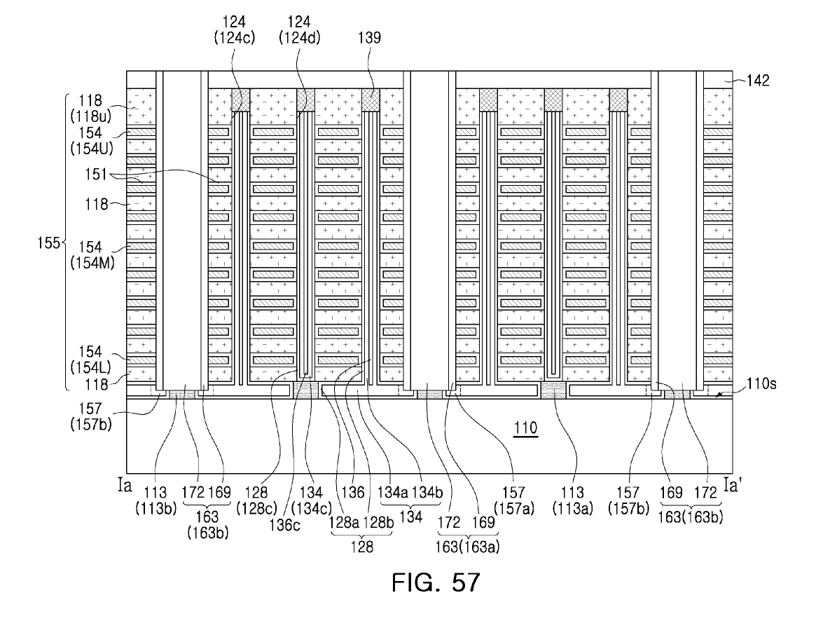

Referring to FIGS. 2, 49, and 57, line structures 163 may be formed in the trenches 145 (S80). Forming the line structures 163 may include forming insulating spacers 169 on side walls of the trenches (145 of FIG. 56), and forming conductive patterns 172 filling the trenches 145.

Referring to FIGS. 3A and 3B, together with FIGS. 2 and 49, a interconnection structure 181 may be provided (S90). Forming the interconnection structure 181 may include forming a second capping insulating layer 183 on the first capping insulating layer 142, forming contact plugs 185p electrically connected to the conductive patterns 172 while passing through the second capping insulating layer 183, forming first wirings 185i electrically connected to the contact plugs 185p, forming a third capping insulating layer 187 covering first wirings 185i on the second capping insulating layer 183, forming bit line lower plugs 189p passing through the first capping insulating layer 142, the second capping insulating layer 183, and the third capping insulating layer 187, forming an intermediate connection pattern 189i electrically connected to the bit line lower plugs 189p on the third capping insulating layer 187, forming a fourth capping insulating layer 191 covering the intermediate connection pattern 189i on the third capping insulating layer 187, forming a bit line upper plug 193p electrically connected to the intermediate connection pattern 189i while passing through the fourth capping insulating layer 191, and forming a second wiring electrically connected to the fourth capping insulating layer 191, that is, a bit line 193i.

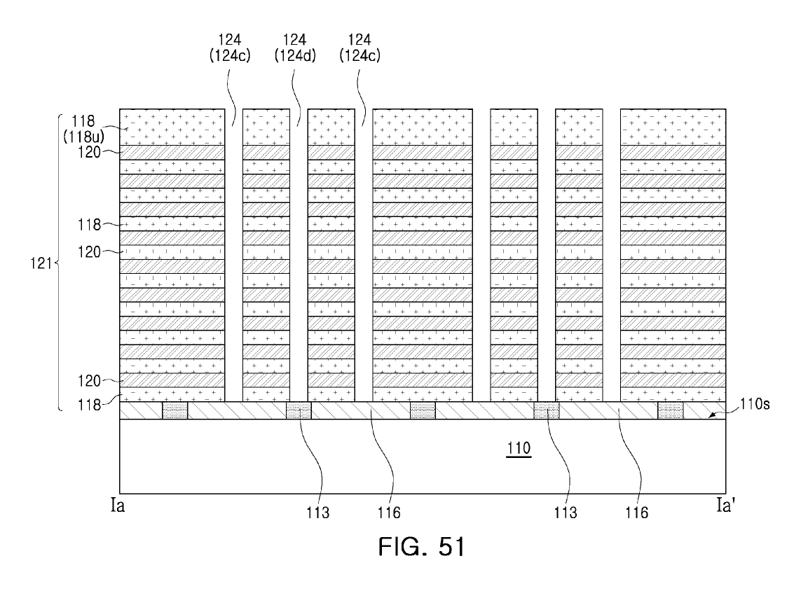

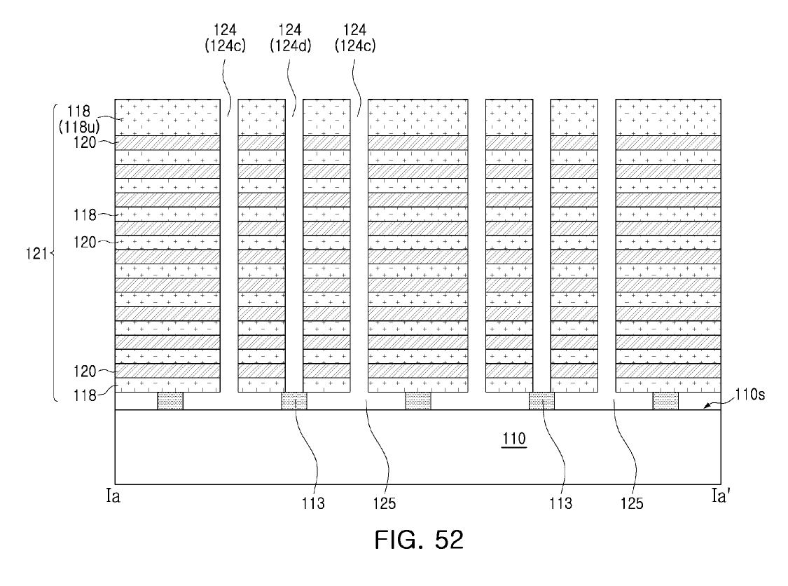

In example embodiments, the support patterns 113 may prevent the molded structure 121 from being collapsed or modified, by the horizontal space (125 of FIG. 52) formed by removing the sacrificial layer (116 of FIG. 51). By the method described above, even when the number of the gate replacement layers 120 of the molded structure 121, which may be replaced with the gate electrodes (154 of FIG. 56), the first gate dielectric structure (128 of FIG. 53) and the channel structure (134 of FIG. 53) may be formed without process defects. Thus, a degree of integration of a three-dimensional semiconductor device may be improved, and reliability may be improved.

As set forth above, according to example embodiments of the disclosure of this application, a three-dimensional semiconductor device capable of improving a degree of integration may be provided. The three-dimensional semiconductor device may include support patterns for supporting a stacked structure including stacked gate electrodes, and a channel structure disposed between the support patterns and passing through the stacked gate electrodes. The structure described above may stably and reliably increase the number of stacked gate electrodes, thereby improving a degree of integration of a semiconductor device.

While example embodiments have been shown and described above, it will be apparent to those skilled in the art that modifications and variations could be made without departing from the scope of the present disclosure, as defined by the appended claims.

What is claimed is:

1. A three-dimensional semiconductor device, comprising:
a stacked structure disposed on a lower structure, and including interlayer insulating layers and gate electrodes, alternately stacked;
a channel structure disposed on the lower structure and spaced apart from the lower structure, the channel structure including a horizontal portion, between the stacked structure and the lower structure, and a plurality of vertical portions extending from a portion of the horizontal portion in a vertical direction, perpendicular to an upper surface of the lower structure;
support patterns disposed on the lower structure and disposed below the stacked structure; and
a gate dielectric structure having a lower portion and upper portions,
wherein the lower portion of the gate dielectric structure is disposed between a lower surface of the horizontal portion of the channel structure and the lower structure, and between an upper surface of the horizontal portion of the channel structure and the stacked structure, and
the upper portions of the gate dielectric structure are disposed between the vertical portions of the channel structure and the stacked structure.

2. The three-dimensional semiconductor device of claim 1, wherein, in the channel structure, the plurality of vertical portions extends continuously, without an interface in the vertical direction, from a portion of the horizontal portion.

3. The three-dimensional semiconductor device of claim 1, wherein a portion of the lower portion of the gate dielectric structure is extended in the vertical direction and is disposed on side surfaces of the support patterns.

4. The three-dimensional semiconductor device of claim 1, further comprising a line structure passing through the stacked structure in the vertical direction.

5. The three-dimensional semiconductor device of claim 4, wherein the line structure includes:
a conductive pattern electrically connected to the horizontal portion of the channel structure, and
insulating spacers on side surfaces of the conductive pattern.

6. The three-dimensional semiconductor device of claim 4, wherein at least a portion of the support patterns overlaps the line structures.

7. The three-dimensional semiconductor device of claim 4, wherein at least a portion of the horizontal portion of the channel structure is disposed between the line structure and the lower structure.

8. The three-dimensional semiconductor device of claim 4, wherein the line structure includes:
a lower material layer in contact with the horizontal portion of the channel structure, a conductive pattern disposed on the lower material layer and spaced apart from the horizontal portion of the channel structure, and
insulating spacers disposed on side surfaces of the conductive pattern.

9. The three-dimensional semiconductor device of claim 4, wherein the line structure includes:
a lower material layer passing through the horizontal portion of the channel structure and the lower portion of the gate dielectric structure, and wherein the line structure is in contact with the horizontal portion of the channel structure and the lower portion of the gate dielectric structure,
a conductive pattern disposed on the lower material layer and spaced apart from the horizontal portion of the channel structure, and
insulating spacers disposed on side surfaces of the conductive pattern.

10. The three-dimensional semiconductor device of claim 1, wherein an interface between the a first support pattern of the support patterns and the lower structure is higher than an interface between the gate dielectric structure and the lower structure.

11. The three-dimensional semiconductor device of claim 1, further comprising:
insulating separation patterns passing through at least a top gate electrode of the gate electrodes; and
additional channel layers disposed between the insulating separation patterns, and extended in a direction toward the lower structure and passing through the gate electrodes.

12. The three-dimensional semiconductor device of claim 11, wherein the additional channel layers are spaced apart from the horizontal portion of the channel structure.

13. The three-dimensional semiconductor device of claim 11, wherein the additional channel layers are extended continuously without an interface from a portion of the horizontal portion of the channel structure.

14. The three-dimensional semiconductor device of claim 11, wherein at least a portion of the support patterns overlaps the additional channel layers.

15. The three-dimensional semiconductor device of claim 1, wherein the lower structure includes a semiconductor substrate, a peripheral circuit structure on the semiconductor substrate, and a lower insulating structure covering the peripheral circuit structure.

16. A three-dimensional semiconductor device, comprising:
a stacked structure disposed on a semiconductor substrate, and including interlayer insulating layers and gate electrodes, alternately stacked;
a channel structure disposed on the semiconductor substrate, the channel structure including a horizontal portion between the stacked structure and the semiconductor substrate and a plurality of vertical portions extending in a vertical direction, perpendicular to an upper surface of the semiconductor substrate, from the horizontal portion;
a line structure passing through the stacked structure in the vertical direction; and
an impurity region disposed in the horizontal portion of the channel structure adjacent to the line structure.

17. The three-dimensional semiconductor device of claim 16, wherein the channel structure has an integral structure formed without an interface between the plurality of vertical portions and the horizontal portion, and is spaced apart from the semiconductor substrate, and
the line structure is in contact with the horizontal portion of the channel structure.

18. A three-dimensional semiconductor device, comprising:
a stacked structure disposed on a semiconductor substrate, the stacked structure including gate electrodes stacked in a vertical direction, perpendicular to an upper surface of the semiconductor substrate;
a channel structure disposed on the semiconductor substrate, and spaced apart from the semiconductor substrate, the channel structure including a horizontal portion between the stacked structure and the semiconductor substrate and a plurality of vertical portions extending continuously in the vertical direction from the horizontal portion;
a line structure passing through the stacked structure in the vertical direction and electrically connected to the horizontal portion of the channel structure;
support patterns disposed on the semiconductor substrate and disposed below the stacked structure; and
a gate dielectric structure having a lower portion and upper portions,
wherein the lower portion of the gate dielectric structure is disposed between a lower surface of the horizontal portion of the channel structure and the semiconductor substrate, and between an upper surface of the horizontal portion of the channel structure and the stacked structure, and
the upper portions of the gate dielectric structure are disposed between the vertical portions of the channel structure and the stacked structure.

19. The three-dimensional semiconductor device of claim 18, further comprising a body connection pattern passing through the horizontal portion of the channel structure and the lower portion of the gate dielectric structure and connected to the semiconductor substrate, the body connection pattern being in contact with the horizontal portion of the channel structure.

20. The three-dimensional semiconductor device of claim 18, wherein the line structure includes a lower material layer passing through the horizontal portion of the channel structure and the lower portion of the gate dielectric structure and in contact with the horizontal portion of the channel structure and the lower portion of the gate dielectric structure, a conductive pattern disposed on the lower material layer and spaced apart from the horizontal portion of the channel structure, and insulating spacers disposed on side surfaces of the conductive pattern.

21-25. (canceled)
